(19) United States
(12) Patent Application Publication
(10) Pub. No.: US 2025/0393432 A1
(43) Pub. Date: Dec. 25, 2025

(54) LIGHT EMITTING DISPLAY DEVICE AND ELECTRONIC APPARATUS

(71) Applicant: Samsung Display Co., LTD., Yongin-si (KR)

(72) Inventors: Baek Min OH, Yongin-si (KR); Soo-Hye RYU, Yongin-si (KR); Hae Chan PARK, Yongin-si (KR); Hong-Jo PARK, Yongin-si (KR); Hae Ju YUN, Yongin-si (KR); Eung Gyu LEE, Yongin-si (KR); HYEMIN LEE, Yongin-si (KR); Eun Je JANG, Yongin-si (KR)

(21) Appl. No.: 19/030,751

(22) Filed: Jan. 17, 2025

(30) Foreign Application Priority Data
Jun. 20, 2024 (KR) 10-2024-0080244

(51) Int. Cl. H10K 59/38; H10K 59/122; H10K 59/65; H10K 59/80

(52) U.S. Cl. CPC H10K 59/38; H10K 59/122; H10K 59/8791; H10K 59/65

(57) ABSTRACT

According to embodiments, a light emitting display device includes a substrate; a plurality of anodes on the substrate; a pixel defining layer having a plurality of first openings that overlap each of the plurality of anodes; a plurality of light emitting layers each provided within the plurality of first openings of the pixel defining layer; a cathode on the plurality of light emitting layers and the pixel defining layer; an encapsulation layer over the cathode; and a plurality of color filters on the encapsulation layer and corresponding to different colors, wherein the plurality of color filters includes a light blocking area of the color filter which at least two color filters among the plurality of color filters overlap, and a plurality of second openings in which only one color filter among the plurality of color filters is provided.

### CROSS-REFERENCE TO RELATED APPLICATION

The present application claims priority to and the benefit of Korean Patent Application No. 10-2024-0080244, filed on Jun. 20, 2024, in the Korean Intellectual Property Office, the entire content of which is hereby incorporated by reference.

### BACKGROUND

### 1. Field

Embodiments of the present disclosure relate to a light emitting display device.

### 2. Description of the Related Art

A display device is a device that displays an image, and includes a liquid crystal display (LCD), an organic light emitting diode (OLED) display, and/or the like.

Display devices are used in various suitable electronic devices such as mobile phones, navigation devices, digital cameras, electronic books, portable game machines, and/or various suitable terminals.

The display device such as the organic light emitting diode may have a structure in which the display device is bent and/or folded using a flexible substrate.

In small electronic devices such as portable phones, optical elements such as cameras and/or optical sensors may be formed in a bezel area (e.g., a peripheral area) around the display area, but as the size of the peripheral area of the display area is gradually decreased while the size of the screen to be displayed is increased, a technology is being developed that allows the camera and/or the optical sensor to be on a back of the display area.

### SUMMARY

Embodiments of the present disclosure provide a light emitting display device that does not include a polarizer on a front side of the display panel and includes a plurality of overlapping color filters to prevent or reduce reflection and/or transmission of external light without including a light blocking layer having a black color, thereby reducing time utilized for a manufacturing process and reducing a manufacturing cost.

Embodiments of the present disclosure provide a light emitting display device that eliminates or reduces drawbacks of an internal pattern being visible to a user and/or an image not being clearly visible due to a reflection of external light by omitting a polarizer from a front side of the display panel.

According to an embodiment, a light emitting display device includes a substrate; a plurality of anodes on the substrate; a pixel defining layer having a plurality of first openings that overlap each of the plurality of anodes; a plurality of light emitting layers each provided within the plurality of first openings of the pixel defining layer; a cathode on the plurality of light emitting layers and the pixel defining layer; an encapsulation layer over the cathode; and a plurality of color filters on the encapsulation layer and corresponding to different colors, wherein the plurality of color filters include a light blocking area of the color filter which at least two color filters among the plurality of color filters overlap, and a plurality of second openings in which only one color filter among the plurality of color filters is provided, and the light blocking area of the color filter has a side of a stepped shape in which an end of the second color filter provided above is provided inward compared to an end of the first color filter provided below among the plurality of color filters.

Among the plurality of color filters, the second color filter provided above may be thicker than the first color filter provided below.

The light blocking area of the color filter may be where the blue color filter, red color filter, and green color filter overlap, and each of the plurality of second openings may overlap one color filter among the blue color filter, the red color filter, and the green color filter.

The light blocking area of the color filter may be where the blue color filter and the red color filter overlap, and each of the plurality of second openings may overlap one color filter among a blue color filter, a red color filter, and a green color filter.

The light emitting display device may further include a plurality of photosensor areas corresponding to optical elements, and a photosensor area first opening is provided around the photosensor area in the pixel defining layer, and a photosensor area second opening is provided in the light blocking area of the color filter.

The photosensor area second opening may be where a blue color filter, a red color filter, and a green color filter are not provided.

The photosensor area second opening may be between adjacent red second opening and blue second opening, and the light blocking area of the color filter may not be between the photosensor area second opening and the red second opening or the blue second opening.

Each planar shape of the plurality of first openings and the plurality of second openings may have a shape of a circle, an ellipse, or a polygon.

At least one selected from among the plurality of first openings and the plurality of second openings may to have an oval shape (e.g., a substantially oval shape).

The first opening and the second opening, which overlap each other on a plane, may be provided at regular intervals on a plane.

A light emitting display device according to an embodiment includes a substrate; a plurality of anodes on the substrate; a pixel defining layer having a plurality of first openings that each overlap the plurality of anodes; a plurality of light emitting layers each provided within the plurality of first openings of the pixel defining layer; a cathode on the plurality of light emitting layers and the pixel defining layer; and an encapsulation layer over the cathode; and a plurality of color filters are on the encapsulation layer and correspond to different colors, wherein the plurality of color filters include a light blocking area of the color filter in which at least two color filters among the plurality of color filters overlap, and a plurality of second openings in which only one color filter among the plurality of color filters is provided, and the light blocking area of the color filter has a shape in which an end or step part of the first color filter below among the plurality of color filters is covered by the second color filter above.

Among the plurality of color filters, the second color filter above may be thicker than the first color filter below.

The light blocking area of the color filter may be where the blue color filter, red color filter, and green color filter overlap, and each of the plurality of second openings may overlap one color filter among the blue color filter, the red color filter, and the green color filter.

The light blocking area of the color filter may be where the blue color filter and the red color filter overlap, and each of the plurality of second openings may overlap one color filter among a blue color filter, a red color filter, and a green color filter.

The light emitting display device may further include a plurality of photosensor areas provided corresponding to optical elements, and a photosensor area first opening is provided around the photosensor area in the pixel defining layer, and a photosensor area second opening is provided in the light blocking area of the color filter.

The photosensor area second opening may be where a blue color filter, a red color filter, and a green color filter are not provided.

The photosensor area second opening may be provided between adjacent red second opening and blue second opening, and the light blocking area of the color filter may not be provided between the photosensor area second opening and the red second opening or the blue second opening.

The planar shape of each of the plurality of first openings and the plurality of second openings may be a circle (e.g., generally a circle), an ellipse (e.g., generally an ellipse), or a polygon.

At least one selected from among the plurality of first openings and the plurality of second openings may have an oval shape (e.g., generally an oval shape).

The first opening and the second opening, which overlap each other on a plane, may be provided at regular intervals on a plane.

According to embodiments, a polarizer and a light blocking layer are not provided on the front side of the display panel, and a plurality of color filters may be overlapped instead of the light blocking layer to prevent or reduce reflection or transmission of external light, thereby reducing a time and a manufacturing cost utilized for the manufacturing process.

By overlapping the plurality of color filters, drawbacks of an internal pattern being visible to the user and/or images not being visible due to external light reflection can be eliminated or reduced.

An electronic apparatus includes a processor to provide input image data; and a light emitting display device to display an image based on the input image data. The light emitting display device includes a substrate; a plurality of anodes on the substrate; a pixel defining layer having a plurality of first openings that overlap each of the plurality of anodes; a plurality of light emitting layers each provided within the plurality of first openings of the pixel defining layer; a cathode on the plurality of light emitting layers and the pixel defining layer; an encapsulation layer over the cathode; and a plurality of color filters on the encapsulation layer and corresponding to different colors, wherein the plurality of color filters include a light blocking area of the color filter which at least two color filters among the plurality of color filters overlap, and a plurality of second openings in which only one color filter among the plurality of color filters is provided, and the light blocking area of the color filter has a side of a stepped shape in which an end of the second color filter provided above is provided inward compared to an end of the first color filter provided below among the plurality of color filters.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic perspective view illustrating a state of use of a display device according to an embodiment.

FIG. 2 is an exploded perspective view of a display device according to an embodiment.

FIG. 3 is a block diagram of a display device according to an embodiment.

FIG. 4 is a schematic perspective view illustrating a state of use of a display device according to another embodiment.

FIG. 5 is a top plan view illustrating an enlarged part of an area of a light emitting display device according to an embodiment.

FIG. 6 is a top plan view of a part of a light emitting display device according to an embodiment.

FIG. 7 is a schematic cross-sectional view along a cross-section line VII-VII of FIG. 6.

FIG. 8 is a schematic cross-sectional view according to a comparative example.

FIG. 9 is a top plan view of a part of a light emitting display device according to another embodiment.

FIG. 10 is a perspective view of a part of a light emitting display device according to an embodiment of FIG. 9.

FIG. 11 to FIG. 13 are schematic cross-sectional views according to another embodiment.

FIGS. 14A-14F are top plan views of parts of a light emitting display device according to various embodiments.

FIG. 15 is a schematic cross-sectional view of a display panel according to an embodiment.

FIG. 16 is a schematic cross-sectional view of a display panel according to another embodiment.

FIG. 17 is a graph showing a transmittance according to a wavelength of a color filter.

FIG. 18 is a cross-sectional view of a light emitting display device according to an embodiment.

### DETAILED DESCRIPTION

The subject matter of the present disclosure will be described more fully hereinafter with reference to the accompanying drawings, in which example embodiments of the disclosure are shown. As those skilled in the art would realize, the described embodiments may be modified in various suitable different ways, all without departing from the spirit or scope of the present disclosure.

The drawings and description are to be regarded as illustrative in nature and not restrictive, and like reference numerals designate like elements throughout the specification.

Further, in the drawings, a size and thickness of each element may be randomly represented for better understanding of the subject matter of the present disclosure and ease of description, and the present disclosure is not limited thereto. In the drawings, the thicknesses of layers, films, panels, areas, etc., may be exaggerated for clarity. In the drawings, for better understanding and ease of description, the thicknesses of some layers and areas may be exaggerated.

It should be understood that when an element such as a layer, film, area, or substrate is referred to as being “on” another element, it can be directly on the other element or intervening elements may also be present. However, when an element is referred to as being “directly on” another element, there are no intervening elements present. Further, in the specification, the word “on” or “above” means on or below the object part, and does not necessarily mean on the upper side of the object part based on a gravitational direction.

In some embodiments, unless explicitly stated to the contrary, the words “include” and “comprise,” and variations such as “includes,” “including,” “comprises” or “comprising,” should be understood to imply the inclusion of stated elements but not the exclusion of any other elements.

Further, throughout the specification, the phrase “on a plane” means viewing a target part from the top, and the phrase “in a cross-section” means viewing a cross-section formed by vertically cutting a target part from the side.

Throughout the specification, “connected” does not mean only when two or more elements are directly connected, but when two or more elements are indirectly connected through other elements, and when they are physically connected or electrically connected, and further, it may be referred to as elements with different names depending on position or function, and may also be referred to as a case in which respective parts that are substantially integrated are linked to each other.

Also, throughout the specification, if (e.g., when) it is said that parts such as a wire, a layer, a film, an area, a plate, and a constituent element are “extended in a first direction or a second direction,” this does not mean only a straight line shape that extends straight in the corresponding direction, but also includes a structure that generally extends along the first or second direction, including a structure that is curved, zigzagged or otherwise extends along the first direction or the second direction.

In some embodiments, electronic devices (e.g., mobile phones, TVs, monitors, laptop computers, etc.) included in display devices and display panels described in the specification, and/or electronic devices included in display devices and display panels, etc. manufactured by manufacturing methods described in the specification are not excluded from the rights herein.

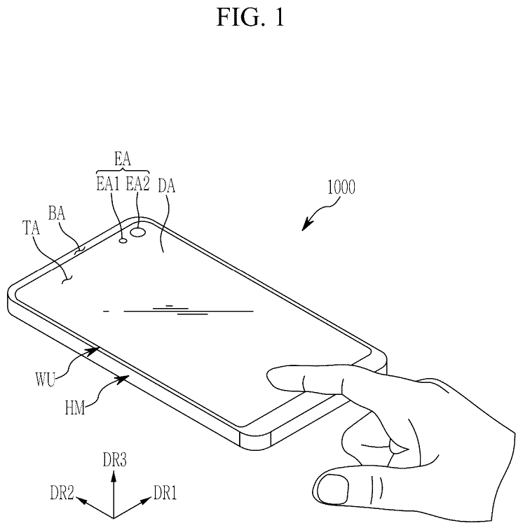

Hereinafter, a schematic structure of the display device is described with reference to FIG. 1 to FIG. 3.

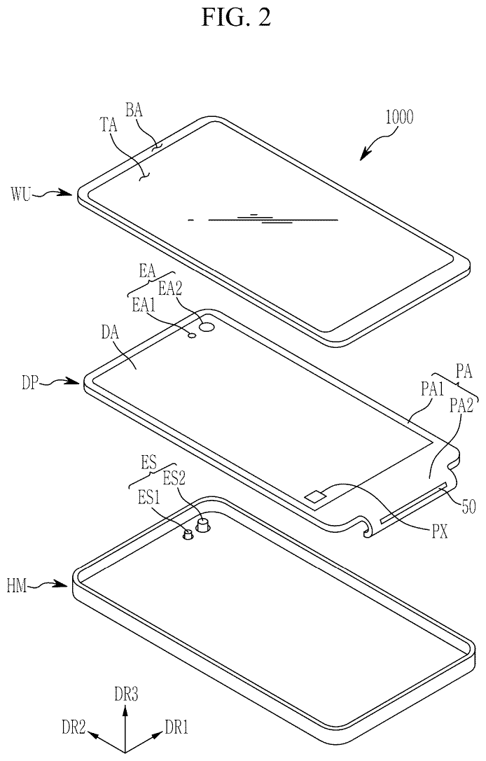

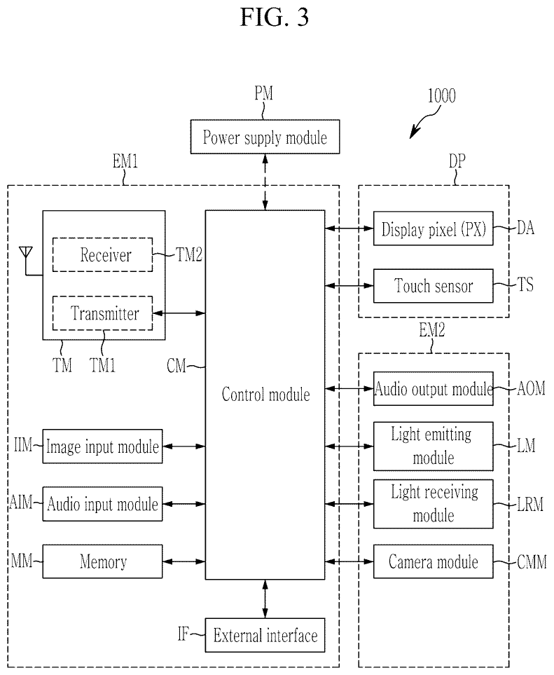

FIG. 1 is a schematic perspective view illustrating a state of use of a display device according to an embodiment. FIG. 2 is an exploded perspective view of a display device according to an embodiment. FIG. 3 is a block diagram of a display device according to an embodiment.

Referring to FIG. 1, a display device 1000 according to an embodiment may display a motion picture and/or a still image, and, as an example, may be used as a display screen of various suitable products such as a television, a laptop, a monitor, a billboard, the Internet of Things (IOT) device, as well as a portable electronic device such as a mobile phone, a smart phone, a tablet personal computer, a mobile communication terminal, an electronic notebook, an electronic book, a portable multimedia player (PMP), a navigation device, an ultra-mobile PC (UMPC), etc. Also, the display device 1000 according to an embodiment may be used in wearable devices such as a smart watch, a watch phone, a glasses-type display, a head mounted display (HMD), etc. Also, a display device 1000 according to an embodiment may be used as an instrument panel of a vehicle, a center fascia of a vehicle and/or a center information display (CID) provided on a dashboard, a room mirror display instead of a side mirror of a vehicle, entertainment for a back seat of a vehicle, and/or a display provided at a rear surface of a front seat. For better comprehension and ease of description, FIG. 1 shows the display device 1000 being used as a smartphone, but the present disclosure is not limited thereto.

The display device 1000 may display an image toward a third direction DR3 on a display surface parallel (e.g., substantially parallel) to a first direction DR1 and a second direction DR2

The display surface on which the image is displayed may correspond to the front surface of the display device 1000 and may correspond to the front surface of a cover window WU. The images may include static images as well as dynamic images.

In the present embodiment, a front (or top) and a back (or bottom) of each member are defined based on the direction in which the image is displayed. The front and rear surfaces may be opposite to each other in the third direction DR3, and the normal directions of the front and rear surfaces may be parallel (e.g., substantially parallel) to the third direction DR3. The separation distance in the third direction DR3 between the front and rear surfaces may correspond to the thickness in the third direction DR3 of the light emitting display panel.

The display device 1000 according to an embodiment may detect a user's input (refer to a hand in FIG. 1) applied from the outside. The user's input may include various suitable types (or kinds) of external inputs such as a part of the user's body, light, heat, and/or pressure. In an embodiment, the user's input is shown with the user's hand applied to the front. However, the present disclosure is not limited thereto. The user's input may be provided in various suitable forms, and the display device 1000 may sense the user's input applied to the side or rear surface of the display device 1000 according to the structure of the display device 1000.

Referring to FIG. 1 and FIG. 2, the display device 1000 may include a cover window WU, a housing HM, a display panel DP, and an optical element ES. In an embodiment, the cover window WU and the housing HM may be combined to constitute the appearance of the display device 1000.

The cover window WU may include an insulating panel (e.g., an electrically insulating panel). For example, the cover window WU may be made of glass, plastic, or a combination thereof.

The front surface of the cover window WU may define the front surface of the display device 1000. The transmissive area TA may be an optically transparent area. For example, the transmissive area TA may be an area having visible ray transmittance (e.g., visible light transmittance) of about 90% or more.

A blocking area BA may define the shape of the transmissive area TA. The blocking area BA is adjacent to the transmissive area TA and may surround the transmissive area TA. The blocking area BA may be an area having relatively low light transmittance (relatively lower light transmittance) compared to the transmissive area TA. The blocking area BA may include an opaque material that blocks or reduces transmission of light (e.g., visible light). The blocking area BA may have a set or predetermined color. The blocking area BA may be defined by a bezel layer provided separately from a transparent substrate that defines the transmissive area TA, or may be defined by an ink layer provided by inserting and/or coloring it into the transparent substrate.

The display panel DP may include a display pixel PX and a driver 50 to display an image, and the display pixel PX is provided within the display area DA and a component area EA. The display panel DP may include the front surface including the display area DA and a peripheral area PA. In an embodiment, the display area DA and the component area EA may be areas where the image is displayed, including the pixels, and may be areas where a touch sensor is provided on the upper side in the third direction DR3 of the pixels concurrently (e.g., simultaneously) to detect an external input.

The transmissive area TA of the cover window WU may overlap at least a part of the display area DA and the component area EA of the display panel DP. For example, the transmissive area TA may overlap the front surface of the display area DA and the component area EA, or may overlap at least a part of the display area DA and the component area EA. Accordingly, the user may perceive the image through the transmissive area TA and/or provide an external input based on the image. However, the present disclosure is not limited thereto. For example, the area where the image is displayed and the area where the external input is detected may be separated from each other (e.g., spaced apart from each other).

The peripheral area PA of the display panel DP may overlap at least partially the blocking area BA of the cover window WU. The peripheral area PA may be an area covered by the blocking area BA. The peripheral area PA may be adjacent to the display area DA and surround the display area DA. The peripheral area PA does not display images, and driving circuits and driving wirings to drive the display area DA may be placed there. The peripheral area PA may include a first peripheral area PA1 provided outside the display area DA and a second peripheral area PA2 including the driver 50, a connection wiring, and a bending area. In the embodiment of FIG. 2, the first peripheral area PA1 is provided on three sides of the display area DA, and the second peripheral area PA2 is provided on the other side of the display area DA. In an embodiment, the display panel DP may be assembled in a flat state

such that the display area DA and the peripheral area PA face the cover window WU. However, the present disclosure is not limited thereto. A part of the peripheral area PA of the display panel DP may be bent. In this case, a part of the peripheral area PA faces the rear surface of the display device 1000, so that the blocking area BA shown on the front surface of the display device 1000 may be reduced, and as shown in FIG. 2, the second peripheral area PA2 is bent to be positioned on the back surface of the display area DA and then assembled.

In some embodiments, the component area EA of the display panel DP may include a first component area EA1 and a second component area EA2. The first component area EA1 and the second component area EA2 may be at least partially surrounded by the display area DA. The first component area EA1 and the second component area EA2 are shown as being separated from each other, but are not limited thereto and may be at least partially connected. The first component area EA1 and the second component area EA2 may be areas in which the optical element (referring to ES of FIG. 2, hereinafter referred to as a component) using infrared rays, visible rays (e.g., visible light), and/or a sound is provided below the first component area EA1 and the second component area EA2.

The display area (DA; which may also be referred to as a main display area

hereinafter) and the component area EA are provided with a plurality of light emitting diodes and a plurality of pixel circuit units that generate and transmit light emitting current to each of the plurality of light emitting diodes. Here, one light emitting diode and one pixel circuit unit are referred to as a pixel PX. In the display area DA and the component area EA, one pixel circuit unit and one light emitting diode may be provided on a one-to-one basis.

The first component area EA1 may include a transmissive unit through which light or/and sound may pass and a display unit including a plurality of pixels. The transmissive unit is provided between the adjacent pixels and is composed of a layer through which light and/or sound can pass. The transmissive unit may be provided between the adjacent pixels, and according to some embodiments, a layer that is impermeable to light of a set or certain wavelength (e.g., visible light) may overlap the first component area EA1. The number of the pixels per unit area (hereinafter referred to as resolution) of the pixels (hereinafter referred to as normal pixels) included in the display area DA and the number of pixels per unit area of the pixels (hereinafter referred to as first component pixels) included in the first component area EA1 may be the same.

The second component area EA2 includes an area (hereinafter, also referred to as a light transmissive area) wherein the light transmissive area may have a structure in which no conductive layer (e.g., electrically conductive layer) or semiconductor layer is provided and in which a layer including a light blocking material, such as, for example, a pixel defining layer and/or at least two or more color filters, may be provided to include an opening that overlaps a position corresponding to the second component area EA2. The number of pixels per unit area of the pixels (hereinafter referred to as a second component pixel) included in the second component area EA2 may be smaller than the number of pixels per unit area of the normal pixels included in the display area DA. As a result, the resolution of the second component pixel may be relatively lower than the resolution of the normal pixel.

Referring to FIG. 3, the display panel DP may further include a touch sensor TS in addition to the display area DA including the display pixel PX. The display panel DP may be viewed by the user from the outside through the transmissive area TA, including the pixel PX, which is a component that generates the image. In some embodiments, the touch sensor TS may be on the pixel PX and may detect external input. The touch sensor TS may detect the external input provided to the cover window WU.

Again, referring to FIG. 2, the second peripheral area PA2 may include a bending part. The display area DA and the first peripheral area PA1 may have a flat state substantially parallel to the plane defined by the first direction DR1 and the second direction DR2, and one side of the second peripheral area PA2 may extend from the flat state, pass through the bending part, and then have the flat state again. As a result, at least a part of the second peripheral area PA2 may be assembled to be bent and on the back side of the display area DA. At least a part of the second peripheral area PA2 overlaps the display area DA on a plane when being assembled, so that the blocking area BA of the display device 1000 may be reduced. However, the present disclosure is not limited thereto. For example, the second peripheral area PA2 may not be bent.

The driver 50 may be mounted on the second peripheral area PA2, and may be mounted on the bending part or provided on one of both sides (e.g., two opposing sides) of the bending part. The driver 50 may be provided in a chip form.

The driver 50 may be electrically connected to the display area DA and the component area EA and may transmit electrical signals to the pixels of the display area DA and the component area EA. For example, the driver 50 may provide data signals to the pixels PX placed in the display area DA. In some embodiments, the driver 50 may include a touch driving circuit and may be electrically connected to the touch sensor TS provided in the display area DA and/or the component area EA. In some embodiments, the driver 50 may be designed to include various suitable circuits in addition to the circuits described above or to provide various suitable electrical signals to the display area DA.

In some embodiments, the display device 1000 may have a pad part provided at the end of the second peripheral area PA2, and may be electrically connected to a flexible printed circuit board (FPCB) including a driving chip by the pad part. Here, the driving chip provided on the flexible printed circuit board may include various suitable driving circuits for driving the display device 1000 and/or connectors for a power supply. According to an embodiment, a rigid printed circuit board (PCB) may be used instead of the flexible printed circuit board.

The optical element ES may be placed under the display panel DP. The optical element ES may include a first optical element ES1 that overlaps the first component area EA1 and a second optical element ES2 that overlaps the second component area EA2. The first optical element ES1 may use infrared light, in which case the first component area EA1 may be overlapped by a layer that is impermeable (or substantially impermeable) to light, such as visible light.

The first optical element ES1 may be an electronic element that uses light and/or sound. For example, the first optical element ES1 may be a sensor that receives and utilizes light, such as an infrared sensor, a sensor that outputs and detects light and/or sound to measure a distance and/or recognize fingerprints, a small lamp that outputs light, and/or a speaker that outputs sound. In embodiments of the electronic elements that utilize light, it is possible to utilize light of various suitable wavelength bands, such as visible light, infrared light, and/or ultraviolet rays (e.g., ultraviolet light).

The second optical element ES2 may be at least one selected from among a camera, an infrared camera (IR camera), a dot projector, an infrared illuminator, and a time-of-flight sensor (ToF sensor).

Referring to FIG. 3, the display device 1000 may include a display panel DP, a power supply module PM, a first electronic module EM1, and a second electronic module EM2. The display panel DP, the power supply module PM, the first electronic module EM1 and the second electronic module EM2 may be electrically connected to each other. In FIG. 3, the display pixel and the touch sensor TS provided in the display area DA among the configurations of the display panel DP are shown as an example.

The power supply module PM may supply power required or utilized for the overall operation of the display device 1000. The power supply module PM may include any suitable battery module generally used in the art.

The first electronic module EM1 and the second electronic module EM2 may include various suitable functional modules to operate the display device 1000. The first electronic module EM1 may be directly mounted on the motherboard electrically connected to the display panel DP, or mounted on a separate substrate and electrically connected to the motherboard through a connector.

The first electronic module EM1 may include a control module CM, a wireless communication module TM, an image input module IIM, an audio input module AIM, a memory MM and an external interface IF. Some of the modules are not mounted on the motherboard and may be electrically connected to the motherboard through a flexible printed circuit board connected thereto.

The control module CM may control the overall operation of the display device 1000. The control module CM may be a microprocessor. For example, the control module CM may activate or deactivate the display panel DP. The control module CM may control other modules such as the image input module IIM and/or the audio input module AIM based on touch signals received from the display panel DP.

The wireless communication module TM may transmit/receive a wireless signal with other terminals using a Bluetooth and/or Wi-Fi line. The wireless communication module TM may transmit/receive voice signals by using a general communication line. The wireless communication module TM includes a transmitter TM1 that modulates and transmits a signal to be transmitted, and a receiver TM2 that demodulates a received signal.

The image input module IIM may process the image signal to be converted into an image data that may be displayed on the display panel DP. The audio input module AIM may receive an external sound signal by a microphone in a recording mode, a voice recognition mode, etc. to be converted into electrical voice data.

The external interface IF may serve as an interface connected to an external charger, a wired/wireless data port, and/or a card socket (e.g., a memory card, a SIM/UIM card).

The second electronic module EM2 may include an audio output module AOM, a light emitting module LM, a light receiving module LRM and a camera module CMM, and at least some of the foregoing may be the optical elements ES, as shown in FIG. 1 and FIG. 2 which may be on the rear surface of the display panel DP. The optical element ES may include the light emitting module LM, the light receiving module LRM and the camera module CMM. In some embodiments, the second electronic module EM2 may be directly mounted on the motherboard, or mounted on a separate substrate and electrically connected to the display panel DP through a connector, or electrically connected to the first electronic module EM1.

The audio output module AOM may convert audio data received from the wireless communication module TM and/or audio data stored in the memory MM to be output (e.g., transmitted) to the outside.

The light emitting module LM may generate and output (e.g., emit) light. The light emitting module LM may output (e.g., emit) infrared light. For example, the light emitting module LM may include an LED element. For example, the light receiving module LRM may detect infrared rays. The light receiving module LRM may be activated when infrared rays above a set or predetermined level are detected. The light receiving module LRM may include a CMOS sensor. After the infrared rays generated by the light emitting module LM are output (e.g., emitted), they are reflected by an external subject (e.g., a user's finger or a face), and the reflected infrared rays may be incident on the light receiving module LRM. The camera module CMM may take (e.g., capture) an external image.

In an embodiment, the optical element ES may additionally include a light sensing sensor and/or a thermal sensing sensor. The optical element ES may detect an external object received through the front surface and/or provide a sound signal such as voice through the front surface to the outside. In some embodiments, the optical element ES may include a plurality of components, and it is not limited to any one embodiment.

Again, referring to FIG. 2, the housing HM may be coupled with the cover window WU. The cover window WU may be provided in front of the housing HM. The housing HM may be combined with the cover window WU to provide a set or predetermined accommodation space. The display panel DP and the optical element ES may be accommodated in a set or predetermined accommodation space provided between the housing HM and the cover window WU.

The housing HM may include a material having relatively high stiffness. For example, the housing HM may include a plurality of frames and/or plates made of glass, plastic, and/or metal, or a combination thereof. The housing HM may reliably protect the components of the display device 1000 accommodated in the interior space from an external impact.

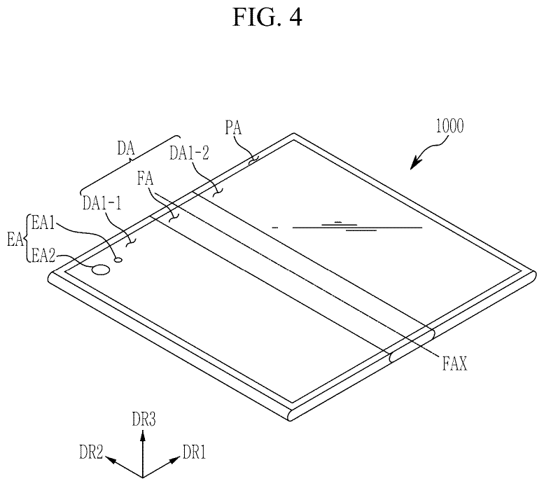

Hereinafter, the structure of the display device 1000 according to another embodiment is described with reference to FIG. 4.

FIG. 4 is a perspective view schematically showing a display device according to another embodiment.

Duplicative description of the same configurations as the above-described constituent elements may not be repeated. The embodiment of FIG. 4 shows a foldable display device of a structure in which the display device 1000 is folded based on a folding axis FAX.

Referring to the embodiment of FIG. 4, the display device 1000 may be a foldable display device. The display device 1000 may be folded outward or inward based on the folding axis FAX. When being folded outward based on the folding axis FAX, the display surface of the display device 1000 is provided on the outside in the third direction DR3, so that images may be displayed in both directions (e.g., two opposing directions). When being folded inward based on the folding axis FAX, the display surface may not be visually recognized from the outside of the display device.

In the embodiment of FIG. 4, the display device 1000 may include a display area DA, a component area EA and a peripheral area PA. The display area DA may be divided into a first-1 display area DA1-1, a first-2 display area DA1-2, and a folding area FA. The first-1 display area DA1-1 and the first-2 display area DA1-2 may be provided at the left and right sides, respectively, based on (or centered on) the folding axis FAX, and the folding area FA may be between the first-1 display area DA1-1 and the first-2 display area DA1-2. In some embodiments, when being folded outward based on the folding axis FAX, the first-1 display area DA1-1 and the first-2 display area DA1-2 are provided at both sides (e.g., two opposing sides) in the third direction DR3, and the images may be displayed in both directions (e.g., two opposing directions). In some embodiments, when being folded inward based on the folding axis FAX, the first-1 display area DA1-1 and the first-2 display area DA1-2 may not be visually recognized from the outside of the display device.

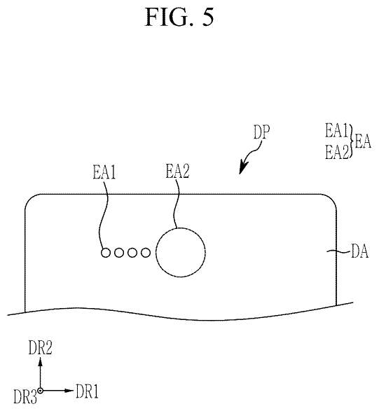

FIG. 5 is a top plan view enlarging and showing a partial area of a light emitting display device according to an embodiment.

FIG. 5 shows a part of the light emitting display panel DP of a light emitting display device according to an embodiment and is illustrated using a display panel for a mobile phone, but the present disclosure is not limited thereto.

In the light emitting display panel DP, the display area DA is provided at the front, and the component area EA is also provided within the display area DA. For example, the component area EA may include the first component area EA1 and the second component area EA2. In the embodiment of FIG. 5, the first component area EA1 is adjacent to the second component area EA2. In the embodiment of FIG. 5, the first component area EA1 is provided to the left of the second component area EA2. The position and number of first component areas EA1 may suitably vary for each embodiment. In FIG. 5, the optical element corresponding to the second component area EA2 may be a camera, and the first optical element ES1 corresponding to the first component area EA1 may be an optical sensor.

A plurality of light emitting diodes LED and a plurality of pixel circuit units to generate and transmit a light emitting current to each of the plurality of light emitting diodes LED are provided in the display area DA. In some embodiments, one light emitting diode LED and one pixel circuit part are referred to as a pixel PX. In the display area DA, one pixel circuit part and one light emitting diode LED are provided on a one-to-one basis. The display area DA hereinafter may also be referred to as “a normal display area.”

In FIG. 5, the structure of the light emitting display panel DP under the cut line is not shown, but the display area DA may be provided under the cut line.

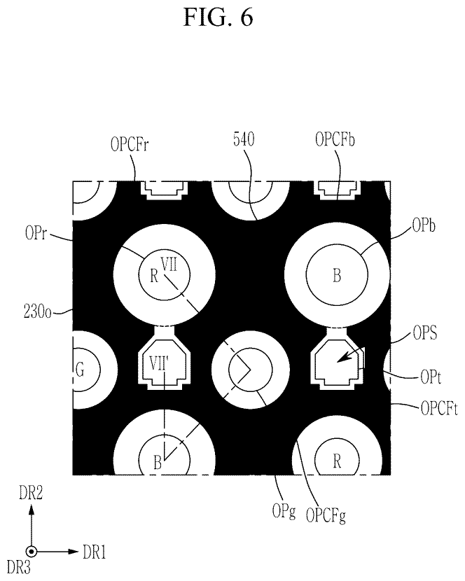

According to some embodiments, the light emitting display panel DP may be largely divided into a lower panel layer and an upper panel layer. The lower panel layer is where the light emitting diodes and the pixel circuit units that make up the pixels are provided, and may include an encapsulation layer (referring to 400 in FIG. 6) that covers them. For example, the lower panel layer is from the substrate (referring to 110 in FIG. 6) to the encapsulation layer, and also includes an anode Anode, a pixel defining layer (referring to 380 in FIG. 6), a light emitting layer (referring to EML in FIG. 6), a spacer (referring to 385 in FIG. 6), a function layer (referring to FL in FIG. 6), a cathode (referring to Cathode in FIG. 6) an insulating layer (e.g., an electrically insulating layer), a semiconductor layer, and a conductive layer (e.g., an electrically conductive layer). In some embodiments, the upper panel layer is a part provided above the encapsulation layer, and may include a sensing insulating layer (referring to 501, 510, 511 of FIG. 6) and a plurality of sensing electrodes (referring to 540, 541 of FIG. 6) capable of detecting a touch, and may include a color filter (referring to 230R, 230G, 230B of FIG. 6) and a planarization layer (referring to 550 of FIG. 6), etc.

The first component area EA1 may be composed of only a transparent layer to allow light to pass through, and a conductive layer (e.g., an electrically conductive layer) or a semiconductor layer may not be provided to allow light to pass through, the lower panel layer has a photosensor area, and an opening (hereinafter, referring to a photosensor area opening) is provided at a position corresponding to the first component area EA1 in the pixel defining layer of the upper panel layer and the light blocking area of the color filter where at least two or more color filters overlap, thereby having a structure that does not (or substantially does not) block light.

In some embodiments, even if the photosensor area is provided in the lower panel layer, if (e.g., when) there is no corresponding opening in the upper panel layer, it may be the display area DA, not the first component area EA1. The first component area EA1 may include a plurality of adjacent photosensor areas, in which the pixels adjacent to the photosensor areas may be included in the first component area EA1. In some embodiments, if (e.g., when) the first optical element ES1 corresponding to the first component area EA1 uses infrared rays (e.g., infrared light) rather than visible rays (e.g., visible light), the first component area EA1 may overlap the light blocking area of the color filter, which overlaps at least two or more color filters that block visible rays (e.g., block or reduce transmission of visible light).

The second component area EA2 may include second component pixels and a light transmissive area, and the space between the adjacent second component pixels may be the light transmissive area.

In some embodiments, a peripheral area may be provided further outside the display area DA. Also, FIG. 5 shows a display panel for a mobile phone, but if (e.g., when) it is a display panel where an optical element may be provided on the back of the display panel, the present embodiment may be applied, and it may also be a flexible display device. In embodiments of the foldable display device among the flexible display devices, the positions of the second component area EA2 and the first component area EA1 may be provided at positions different from those shown in FIG. 5.

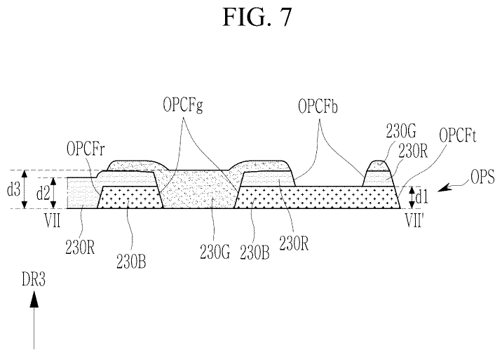

Hereinafter, the structure of the light emitting display panel DP according to an embodiment is described with respect to FIG. 6 and FIG. 7.

FIG. 6 is a top plan view of a part of a light emitting display device according to an embodiment. FIG. 7 is a schematic cross-sectional view along a cross-section line VII-VII′ of FIG. 6.

First, the planar structure is described with respect to FIG. 6.

FIG. 6 is the plan view of the part of the light emitting display device viewed from the front and shows a light blocking area 2300 of a color filter provided in the upper panel layer, second openings OPCFr, OPCFg, OPCFb, and OPCFt of the color filter, openings OPr, OPg, OPb, and Opt of the pixel defining layer, and a sensing electrode 540.

The light blocking area 2300 of the color filter is the area where at least two of three color filters overlap, and is the area that blocks or reduces transmission of light by providing a light blocking layer that has a black color. In FIG. 6, the light blocking area 2300 of the color filter is shown by a dark color to indirectly show that light is blocked.

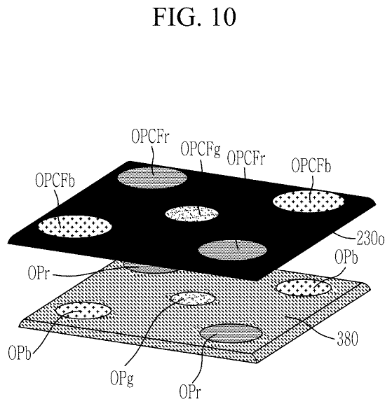

The openings OPr, OPg, OPb, and Opt of the pixel defining layer are openings provided in the pixel defining layer (referring to 380 in FIG. 10), and are openings partitioned by the pixel defining layer as an area where the pixel defining layer is not provided. The openings of the pixel defining layer may be divided into openings (OPr, OPg, OPb; also referred to as first openings hereinafter) corresponding to the light emitting area and openings (OPt; also referred to as a first opening of the photosensor area hereinafter) corresponding to the photosensor area OPS. In some embodiments, the light emitting area may correspond to the area where the light emitting layer of the light emitting diode is provided, and is illustrated by being divided into red (R), green (G), and blue (B) in FIG. 6

The second openings OPCFr, OPCFg, OPCFb, and OPCFt of the color filter light blocking area is a part other than the light blocking area 2300 of the color filter, where one of the three color filters may be provided, and may be divided into the opening (OPCFr, OPCFg, OPCFb; also referred to as a second opening hereinafter) corresponding to the light emitting area and the opening (OPCFt; also referred to as a photosensor area second opening hereinafter) corresponding to the photosensor area OPS. Here, none of the three color filters may be provided in the photosensor area second opening OPCFt.

The sensing electrode 540 is provided below the light blocking area 230o of the color filter and may not be visible from the front of the actual light emitting display device, but is illustrated to show the flat position in FIG. 6. Referring to FIG. 6, the sensing electrode 540 is provided in an area that extends in a diagonal direction and does not overlap the second openings OPCFr, OPCFg, OPCFb, and OPCFt of the color filter. The sensing electrode 540 may be divided into two electrically isolated electrodes.

Referring to FIG. 6, the openings OPr, OPg, and OPb of the pixel defining layer and the second openings OPCFr, OPCFg, and OPCFb of the color filter light blocking area are provided around the light emitting areas R, G, and B, and the photosensor area opening OPt and the photosensor area second opening OPCFt of the pixel defining layer are provided around the photosensor area OPS.

Some of the second openings OPCFr, OPCFg, OPCFb, and OPCFt provided in the color filter light blocking area may be connected to each other, so that the light blocking area 2300 of the color filter may not be provided between them. For example, in FIG. 6, each of the second openings OPCFr and OPCFb is connected to the adjacent photosensor area second opening OPCFt, so that the light blocking area of the color filter is not provided between them. However, because the second openings OPCFr and OPCFb have a color filter of one corresponding color each, while the photosensor area second opening OPCFt of the photosensor area has no color filter, the two openings may be distinguished by the boundary of the color filter.

For example, in the embodiment of FIG. 6, the photosensor area second opening OPCFt is provided between the red second opening OPCFr and the blue second opening OPCFb adjacent in the second direction DR2, and between two green second openings OPCFg adjacent in the first direction DR1, and the light blocking area 2300 of the color filter is not provided between the photosensor area second opening OPCFt and the red second opening OPCFr or the blue second opening OPCFb.

In the embodiment of FIG. 6, the openings OPr, OPg, and OPb of the pixel defining layer and the second openings OPCFr, OPCFg, and OPCFb of the color filter light blocking area 2300 are each shown as having a circular planar shape, but may have an elliptical shape (e.g., a generally elliptical shape) or a polygonal shape or a structure having chamfers at the corners of a polygon. In some embodiments, the openings OPr, OPg, and OPb of the pixel defining layer and the second openings OPCFr, OPCFg, and OPCFb of the color filter light blocking area 2300 may have different planar shapes.

In the embodiment of FIG. 6, the openings OPr, OPg, and OPb of the pixel defining layer may each be formed with different areas for each color, and the openings OPr, OPg, and OPb of the pixel defining layer with the same color may have the same areas. In some embodiments, the second openings OPCFr, OPCFg, and OPCFb of the color filter light blocking area 2300 may also have different areas for each color, and the second openings OPCFr, OPCFg, and OPCFb of the color filter light blocking area 2300 of the same color may have the same areas. According to an embodiment, the entire area of the green second opening OPCFg can be 60% of the entire display area, and may also be 50% or more and 70% or less of the entire display area.

Hereinafter, the cross-sectional structure along the cross-section line of FIG. 6 is described with respect to FIG. 7.

FIG. 7 does not show the sensing electrode, but only shows the structure in which the color filters 230R, 230G, and 230B are stacked.

In the embodiment of FIG. 7, the light blocking area (referring to 2300 in FIG. 6) of the color filter corresponds to the area where the red color filter 230R, the green color filter 230G, and the blue color filter 230B overlap, and according to an embodiment, at least one of the three color filters may not overlap.

Referring to FIG. 7, the color filters 230R, 230G, and 230B have a structure in which the color filter formed first is formed thinly, and the color filter formed subsequently is formed thickly. For example, the color filter provided below is formed thicker than the color filter provided above. In some embodiments, the thickness is the thickness in the area that does not overlap with other color filters, not the thickness in the light blocking area of the color filter, but the thickness in the second openings OPCFr, OPCFg, and OPCFb of the light blocking area of the color filter. Referring to FIG. 7, the blue color filter 230B formed first is formed with the thinnest thickness d1, the red color filter 230R formed second is formed with the medium thickness d2, and the green color filter 230G formed last is formed with the thickest thickness d3.

In FIG. 7, only the red color filter 230R is provided in the red second opening OPCFr of the color filter light blocking area, only the green color filter 230G is provided in the green second opening OPCFg, and only the blue color filter 230B is provided in the blue second opening OPCFb. In some embodiments, the second openings OPCFr, OPCFg, and OPCFb in the color filter light blocking area may be defined as openings provided in a color filter of a different color that is provided at the bottom. For example, in FIG. 7, the red second opening OPCFr and the green second opening

OPCFg may correspond to the opening provided at the blue color filter 230B, and the blue second opening OPCFb may correspond to the opening provided at the red color filter 230R.

Referring to FIG. 7, the photosensor area second opening OPCFt may not have the color filters 230R, 230G, and 230B, and corresponds to the opening provided at the blue color filter 230B provided at the bottom. According to an embodiment, one color filter may be provided in the photosensor area second opening OPCFt.

In FIG. 7, the side of the color filter light blocking area has a step-like shape. For example, in the side of the color filter light blocking area exposed by the second opening, the color filter provided above is formed with the narrower width than the color filter provided below, and the end of the color filter provided above is provided closer to the inside than the end of the color filter provided below, thereby forming the step-like structure. However, according to an embodiment, the color filter provided above may have a non-step-like shape in which the color filter above is formed with the wider width and the end or step part of the color filter provided below is covered by the color filter provided above.

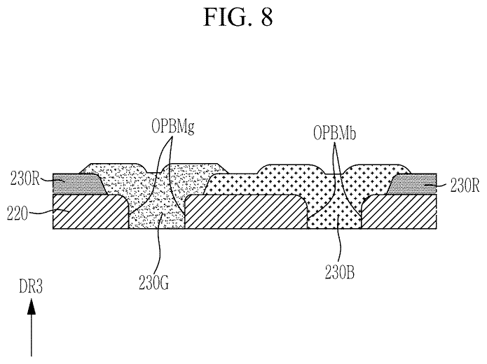

Below, the embodiments of FIG. 6 and FIG. 7 are compared with a comparative example of FIG. 8.

FIG. 8 is a schematic cross-sectional view according to a comparative example.

In the comparative example of FIG. 8, a light blocking layer 220 may be provided, and an area where the light blocking layer 220 is provided may correspond to the light blocking area (referring to 2300 of FIG. 6) of the color filter of FIG. 6 and FIG. 7. In some embodiments, the second openings OPCFr, OPCFg, and OPCFb of the color filter light blocking area of FIG. 6 and FIG. 7 may correspond to the second openings OPBMg and OPBMb of the light blocking layer 220.

In the comparative example of FIG. 8, there is a part where the plurality of color filters overlap, but this part is provided above the light blocking layer 220, so the area where light is blocked is basically controlled by the light blocking layer 220.

However, in a comparative example such as FIG. 8, compared to the embodiments of FIG. 6 and FIG. 7, a separate process for forming the light blocking layer 220 is utilized, which has the drawback of increasing manufacturing time and manufacturing cost. In contrast, the embodiments of FIG. 6 and FIG. 7 may have the merit of lower manufacturing time and lower manufacturing cost (e.g., by omitting a separate process for forming the light blocking layer 220).

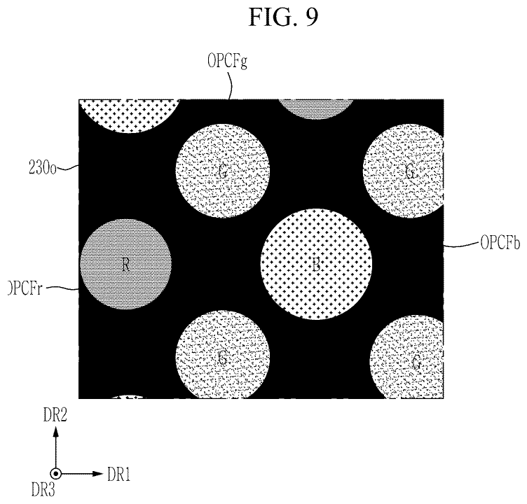

Below, the structure of the color filter and the pixel defining layer of another light emitting display device will be described in more detail with respect to FIG. 9 and FIG. 10.

FIG. 9 is a top plan view of a part of a light emitting display device according to another embodiment. FIG. 10 is a perspective view of a part of a light emitting display device according to the embodiment of FIG. 9.

First, FIG. 9 does not show the sensing electrode 540, but only shows the light blocking area 2300 of the color filter and the second openings OPCFr, OPCFg, and OPCFb visible from the front of the light emitting display device. The light emitting display device according to the embodiment of FIG. 9 does not include a photosensor area.

However, referring to FIG. 10, it also shows the pixel defining layer 380 provided below the light blocking area 2300 of the color filter and the openings OPr, OPg, and OPb positioned in the pixel defining layer 380. In some embodiments, the pixel defining layer 380 may be formed of a material having a black color. For example, the pixel defining layer 380 according to an embodiment may be formed of a black colored organic material of a negative type (or kind). The organic material having the black color may include the light blocking material, and the light blocking material may include carbon black, carbon nanotubes, a resin and/or paste containing a black dye, metal particles, for example, nickel, aluminum, molybdenum, and alloys thereof, metal oxide particles (e.g., chromium nitride), etc. The pixel defining layer 380 may have a black color by including a light blocking material, and may have a characteristic that light is not reflected and is absorbed/blocked. Because the negative type (or kind) is used as the organic material, it may have a characteristic that the part covered by the mask is removed.

The structure of the second openings OPCFr, OPCFg, and OPCFb of the light blocking area 2300 of the color filter may have a one-to-one correspondence with the openings OPr, OPg, and OPb of the pixel defining layer 380, respectively. Here, the openings OPr, OPg, and OPb of the pixel defining layer 380 and the second openings OPCFr, OPCFg, and OPCFb of the color filter light blocking area 2300 are each shown as having a circular planar shape, but may have an elliptical shape (e.g., a generally elliptical shape) or a polygonal shape or a structure having chamfers at the corners of a polygon. In some embodiments, the openings OPr, OPg, and OPb of the pixel defining layer 380 and the second openings OPCFr, OPCFg, and OPCFb of the color filter light blocking area 2300 may have different planar shapes.

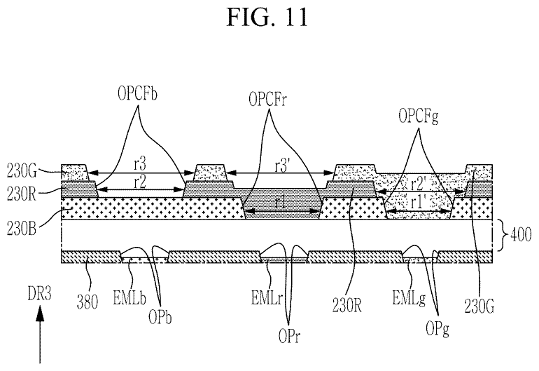

The light emitting display device according to the embodiments of FIG. 9 and FIG. 10 may have one of the cross-section structures of FIG. 11 to FIG. 13, according to an embodiment.

FIG. 11 to FIG. 13 are schematic cross-sectional views according to another embodiment.

First, the cross-sectional structure of FIG. 11 is described.

FIG. 11 shows only from the pixel defining layer 380 to the color filters 230R, 230G, and 230B, as well as the encapsulation layer 400 and the light emitting layers EMLr, EMLg, and EMLb.

Within the openings OPr, OPg, and OPb of the pixel defining layer 380, corresponding light emitting layers EMLr, EMLg, and EMLb are provided respectively. Each light emitting layer EMLr, EMLg, and EMLb corresponds to a light emitting area, which is the part of the light emitting diode where light is emitted. The light emitting diode further includes an anode and a cathode, and the anode may be provided below the light emitting layers EMLr, EMLg, and EMLb, and the cathode may be formed entirely covering the light emitting layers EMLr, EMLg, and EMLb and the pixel defining layer 380, but is omitted in FIG. 11.

The encapsulation layer 400 is provided above the pixel defining layer 380 and the light emitting layers EMLr, EMLg, and EMLb. The encapsulation layer 400 is a layer for blocking or reducing the transmission of moisture and/or air to the light emitting layers EMLr, EMLg, and EMLb, and may include at least one inorganic layer and at least one organic layer. According to an embodiment, the encapsulation layer 400 may include one organic layer provided between two inorganic layers.

The openings OPr, OPg, and OPb of the pixel defining layer 380 may be formed with a narrower width than the second openings OPCFr, OPCFg, and OPCFb of the corresponding color filter light blocking areas. For example, the width of the pixel defining layer 380 may be formed to be wider than the color filter light blocking area.

In FIG. 11, the color filters 230R, 230G, and 230B have a structure in which the color filter formed first is formed thinly, and the color filter formed subsequently is formed thickly. In some embodiments, the thickness is the thickness in the area that does not overlap other color filters, not the thickness in the light blocking area of the color filter, but the thickness in the second openings OPCFr, OPCFg, and OPCFb of the light blocking area of the color filter. Referring to FIG. 11, the blue color filter 230B formed first is formed with the thinnest thickness, the red color filter 230R formed second is formed with the medium thickness, and the green color filter 230G formed last is formed with the thickest thickness.

In FIG. 11, only the red color filter 230R is provided in the red second opening OPCFr of the color filter light blocking area, only the green color filter 230G is provided in the green second opening OPCFg, and only the blue color filter 230B is provided in the blue second opening OPCFb. In some embodiments, the second openings OPCFr, OPCFg, and OPCFb in the color filter light blocking area may be defined as openings provided in a color filter of a different color that is provided at the bottom. For example, in FIG. 11, the red second opening OPCFr and the green second opening OPCFg may correspond to the opening provided at the blue color filter 230B, and the blue second opening OPCFb may correspond to the opening provided at the red color filter 230R.

In some embodiments, corresponding to the blue second opening OPCFb, the red color filter 230R may have an opening formed with a width of r2, the green color filter 230G may have an opening formed with a width of r3, and the blue second opening OPCFb may have a width of r2.

Corresponding to the red second opening OPCFr, the blue color filter 230B may have an opening formed with a width of r1, the green color filter 230G may have an opening formed with a width of r3′, and the red second opening OPCFr may have a width of r1.

Corresponding to the green second opening OPCFg, the blue color filter 230B may have an opening formed with a width of r1′, the red color filter 230R may have an opening formed with a width of r2′, and the green second opening OPCFg may have a width of r1′.

Among the corresponding openings provided in each color filter 230R, 230G, and 230B, the opening formed at the upper part may be formed with a larger width than the opening provided at the corresponding lower part.

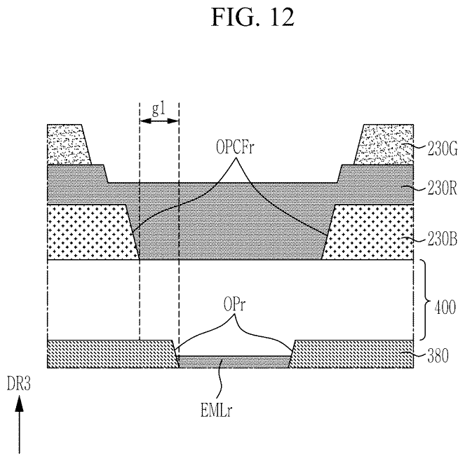

Below, the cross-sectional structure of the color filter light blocking area having a stepped side is described with respect to FIG. 12.

In FIG. 12, as shown in FIG. 11, only the pixel defining layer 380 to the color filters 230R, 230G, and 230B are shown, the encapsulation layer 400 and the light emitting layers EMLr, EMLg, and EMLb are also illustrated, and the anode and the cathode are omitted.

In FIG. 12, only the red second opening OPCFr is shown, and the step part of the red color filter 230R corresponding to the red second opening OPCFr is not covered by the green color filter 230G. For example, the end of the green color filter 230G, which is provided above, is provided inside compared to the end of the red second opening OPCFr, which is provided below. As a result, the side of the color filter light blocking area has a stepped structure.

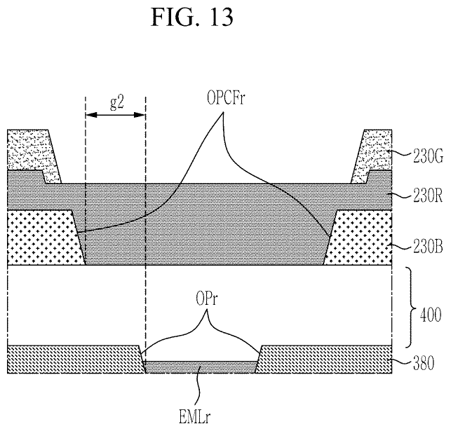

Hereinafter, the cross-sectional structure of the color filter light blocking area having a non-stepped side is described with respect to FIG. 13.

In FIG. 13, as in FIG. 11 and FIG. 12, only the pixel defining layer 380 to the color filters 230R, 230G, and 230B are illustrated, and the encapsulation layer 400 and the light emitting layers EMLr, EMLg, and EMLb are illustrated, while the anode and the cathode are omitted.

The red second opening OPCFr in FIG. 13 has a non-stepped structure. For example, the stepped part of the red second opening OPCFr provided below is covered by the green color filter 230G provided above. According to an embodiment, the end of the red second opening OPCFr provided below may be covered by the green color filter 230G provided above.

Comparing FIG. 12 and FIG. 13, in FIG. 12, a horizontal gap between the red opening OPr of the pixel defining layer 380 and the red second opening OPCFr of the color filter light blocking area has a value g1, but in FIG. 13, a horizontal gap between the red opening OPr of the pixel defining layer 380 and the red second opening OPCFr of the color filter light blocking area has a value g2. In some embodiments, the value g1 according to an embodiment may be 5.72 μm, and the value g2 may be greater than the value g1 by 0.5 μm or more and 2 μm or less as a value larger than the value g1. The width of the red second opening OPCFr corresponds to the width of the opening provided at the blue color filter 230B, and the value g1 has a smaller value than the value g2, so that the gap between the steps of the red color filter 230R provided above the blue color filter 230B is formed larger in the embodiment of FIG. 13 than in the embodiment of FIG. 12. Therefore, in the embodiment of FIG. 12, the stepped part of the red color filter 230R is exposed by the green color filter 230G, thereby having the step-like side surface, but in the embodiment of FIG. 13, the step part of the red color filter 230R is covered by the green color filter 230G, thereby having the non-step-like side surface. However, according to an embodiment, even if (e.g., when) the size of the opening provided at the blue color filter 230B is the same, the width of the green color filter 230G may also be intentionally increased to cover the stepped part of the red color filter 230R, thereby forming the non-stepped side surface. The horizontal gap value between the red opening OPr of the pixel defining layer 380 and the red second opening OPCFr of the color filter light blocking area may be determined by considering the color view from the side, such as, for example, at an angle of 45 degrees.

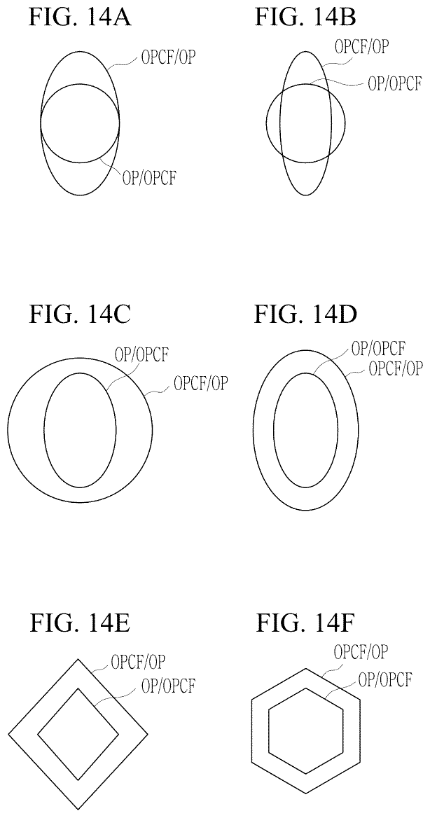

In the above, the embodiment in which the openings OPr, OPg, and OPb of the pixel defining layer 380 and the second openings OPCFr, OPCFg, and OPCFb of the color filter light blocking area are all circular in the planar shape has been mainly described. However, according to an embodiment, they may have various suitable planar shapes as shown in FIG. 14.

FIG. 14 is a top plan view of a part of a light emitting display device according to various embodiments.

FIG. 14 shows an example of an embodiment where at least one of the opening OP of the pixel defining layer and the second opening OPCF of the color filter light blocking area is not circular in the planar shape.

Firstly, referring to the embodiments of FIG. 14A, FIG. 14B, and FIG. 14C, FIG. 14A, FIG. 14B, and FIG. 14C illustrate embodiments in which one of the opening OP of the pixel defining layer and the second opening OPCF of the color filter light blocking area is circular in a planar shape, while the other is elliptical.

The embodiment of FIG. 14A is an embodiment in which the circle is provided inside the ellipse, and the ellipse and the circle are in contact. According to an embodiment, the circle may be provided and in contact with the inside of the ellipse.

The embodiment of FIG. 14B is an embodiment in which the circle and the ellipse partially overlap while including areas in which they do not overlap, and is an embodiment in which the boundaries of the circle and the ellipse intersect.

The embodiment of FIG. 14C is an embodiment in which the entire ellipse is provided inside the circle, and the boundaries do not meet. According to an embodiment, the circles may be provided entirely inside the ellipse, and their boundaries thereof may not meet.

FIG. 14D, FIG. 14E, and FIG. 14F illustrate embodiments in which the opening OP of the pixel defining layer and the second opening OPCF of the color filter light blocking area have planar shapes rather than circles. FIG. 14D, FIG. 14E, and FIG. 14F illustrate embodiments in which the planar shapes of the opening OP of the pixel defining layer and the second opening OPCF of the color filter light blocking area are the same, but the areas are formed differently. In FIG. 14D, FIG. 14E, and FIG. 14F, the opening OP of the corresponding pixel defining layer and the second opening OPCF of the corresponding color filter light blocking area may be formed at regular intervals.

The embodiment of FIG. 14D is an embodiment in which both ellipses are formed in an elliptical shape, and the long axis directions of two ellipses are the same. According to an embodiment, the longitudinal directions in the single light emitting display device may be provided in various suitable directions. According to some embodiments, the major axis directions of the two ellipses may be different.

The embodiments of FIG. 14E are all formed in a rhombus shape, and the arrangement direction of each rhombus is the same. According to an embodiment, the rhombus-shaped corners may have a chamfered structure.

The embodiments of FIG. 14F are all formed in a hexagonal shape, and the arrangement direction of each hexagon is the same. According to an embodiment, the hexagon-shaped corners may have a chamfered structure.

According to an embodiment, the opening OP of the pixel defining layer or the second opening OPCF of the color filter light blocking area may be formed into various suitable polygons such as octagons, and may have a structure having chamfered corners.

As shown in FIG. 14A, FIG. 14B, and FIG. 14C, the planar shapes of the second opening OPCF of the color filter light blocking area and the opening OP of the pixel defining layer may have different planar shapes.

The opening OP part of the pixel defining layer, which is formed larger than the second opening OPCF of the color filter light blocking area, may not be visible from the front because it is covered by the color filter light blocking area.

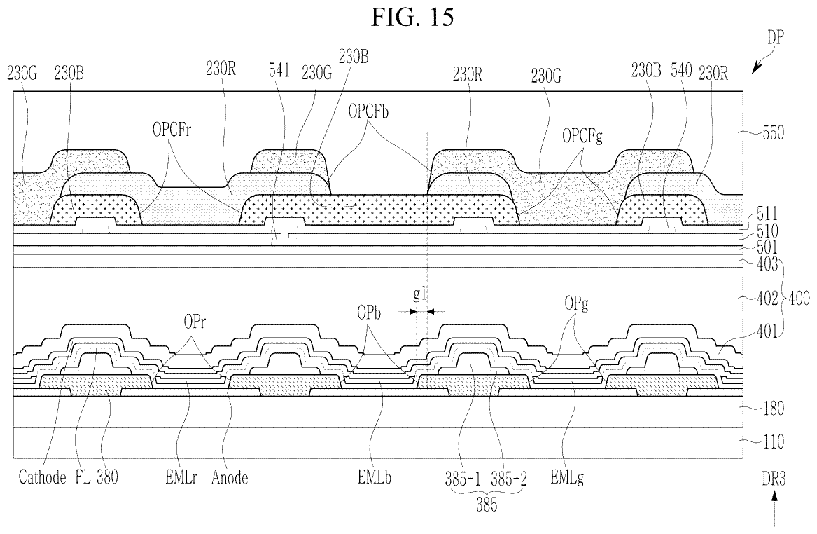

Above, the structure of the light emitting display device has been schematically described, and hereinafter the structure of the light emitting display panel included in the light emitting display device is described in further detail with respect to FIG. 15 for the structure of the light emitting display panel DP.

FIG. 15 is a schematic cross-sectional view of a display panel according to an embodiment.

The light emitting display panel DP according to an embodiment may display images by providing a light emitting diode on a substrate 110, include a plurality of sensing electrodes 540 and 541 to sense a touch, and include color filters 230R, 230G, and 230B so that light emitted from the light emitting diode also has the color characteristics of the color filters 230R, 230G, and 230B. In some embodiments, a light blocking layer formed in black color to block visible light is not formed, and instead of the light blocking layer, at least two or more color filters are overlapped to block visible light (or reduce transmission of visible light).

The area where at least two or more color filters overlap to block visible light (or reduce transmission of visible light) is referred to as the light blocking area of the color filter, and in the embodiment of FIG. 15, the blue color filter 230B, the red color filter 230R, and the green color filter 230G are sequentially stacked. The order in which the color filters are stacked may suitably vary depending on the embodiment.

In some embodiments, a polarizer is not formed on the front surface of the light emitting display panel DP according to an embodiment, and instead, while the pixel defining layer 380 is formed of the black organic material, the light blocking area of the color filters in which at least two or more color filters overlap is formed on the pixel defining layer 380, so that even if external light is incident on the inside, it is not reflected from the anode or the like and transmitted to the user.

The light emitting display panel DP according to an embodiment is described in more detail as follows.

The substrate 110 may include a material that does not bend due to a rigid characteristic such as glass, or a flexible material that can be bent, such as plastic and/or polyimide.

A plurality of thin film transistors are on the substrate 110, but they are omitted in FIG. 15, and only an organic layer 180 covering the thin film transistors is shown. One pixel includes the light emitting diode (LED) and the pixel circuit unit in which a plurality of transistors and capacitors that transmit a light emitting current to the light emitting diode (LED) are provided. In FIG. 15, the pixel circuit unit is not shown, and the structure of the pixel circuit unit may suitably vary according to an embodiment. FIG. 15 shows the organic layer 180 covering the pixel circuit unit.

On the organic layer 180, the light emitting diode (LED) including an anode Anode, a light emitting layer EML and a cathode Cathode is placed.

The anode Anode may be composed of a single layer including a transparent conductive oxide film and a metal material, or a multilayer including the foregoing. The transparent conductive oxide film may include indium tin oxide (ITO), poly-ITO, indium zinc oxide (IZO), indium gallium zinc oxide (IGZO) and indium tin zinc oxide (ITZO), and the metal material may include silver (Ag), molybdenum (Mo), copper (Cu), gold (Au) and/or aluminum (Al), etc.

The light emitting layer EML may be formed of an organic light emitting material, and the adjacent light emitting layers EML may display different colors. In some embodiments, each light emitting layer EML may display light of the same color due to the color filters 230R, 230G, and 230B provided thereon. According to an embodiment, the light emitting layer EML may have a structure (also referred to as a tandem structure) in which a plurality of light emitting layers are stacked.

A pixel defining layer 380 is provided above the organic layer 180 and the anode Anode, an opening (OP; also referred to as a first opening hereinafter) is formed in the pixel defining layer 380, the opening overlaps a part of the anode, and the light emitting layer EML is provided above the anode Anode exposed by the opening OP. The light emitting layer EML may be provided only within the opening of the pixel defining layer 380, and is separated from the adjacent light emitting layer EML by the pixel defining layer 380.

The pixel defining layer 380 may be formed of an organic material having a negative-type black color. The organic material having a black color may include the light blocking material, and the light blocking material may include a resin and/or a paste including a carbon black, a carbon nanotube, and a black dye, metal particles, such as, for example, nickel, aluminum, molybdenum, and/or alloys thereof, metal oxide particles (e.g., chromium nitride), and/or the like. The pixel defining layer 380 may have a black color including a light blocking material, and may have a characteristic that light is not reflected and is absorbed/blocked. Because the negative type (or kind) uses the organic material, it may have a characteristic that the part covered by the mask is removed.

A spacer 385 is on the pixel defining layer 380. The spacer 385 includes a first part 385-1 having a high height and provided in a narrow area and a second part 385-2 having a low height and provided in a wide area. FIG. 15 shows that the first part 385-1 and the second part 385-2 are separated by a dotted line in the spacer 385. In some embodiments, the first part 385-1 may provide a role of securing rigidity against the pressing pressure by enhancing the scratch resistance. The second part 385-2 may serve as a contact assistant between the pixel defining layer 380 and a functional layer FL above. The first part 385-1 and the second part 385-2 may be formed of the same material, and may be formed of a positive-type photosensitive organic material, for example, photosensitive polyimide (PSPI) may be used. Because it has a positive characteristic, the part not covered by the mask may be removed. The spacer 385 is transparent, so light may be transmitted and/or reflected by the spacer 385.

In some embodiments, the pixel defining layer 380 may be formed in the negative type (or kind), and the spacer 385 may be formed in a positive type (or kind), and they may include materials of the same type (or kind).

At least a part of the upper surface of the pixel defining layer 380 is covered by the spacer 385, and the edge of the second part 385-2 has a structure that is spaced apart from the edge of the pixel defining layer 380 so that the part of the pixel defining layer 380 has a structure that is not covered by the spacer 385. The second part 385-2 may reinforce the adhesion characteristic between the pixel defining layer 380 and the functional layer FL by covering even the upper surface of the pixel defining layer 380 where the first part 385-1 is not provided. In some embodiments, the spacers 385 are only provided in areas that overlap in-plane with the light blocking area of the color filter that block visible light (or reduce transmission of visible light) by overlapping at least two color filters, such that the spacers 385 may not be visible in the light blocking area of the color filter when viewed from the front of the display panel DP.

The functional layer FL may be provided above the spacer 385 and the exposed pixel defining layer 380, and the functional layer FL may be on the entire surface of the light emitting display panel DP or may be provided in all areas except for some areas such as, for example, the light transmissive area of the second component area EA2.

The functional layer FL may include an electron injection layer, an electron transport layer, a hole transport layer, and a hole injection layer (HIL), and the functional layer FL may be provided above or below the light emitting layer EML. For example, the hole injection layer, the hole transport layer, the light emitting layer EML, the electron transport layer, the electron injection layer, and the cathode Cathode may be sequentially provided on the anode Anode, whereby the hole injection layer and the hole transport layer among the functional layer FL may be provided under the light emitting layer EML, and the electron transport layer and the electron injection layer may be provided on the light emitting layer EML.

The spacer 385 may reduce a defect rate due to a pressing pressure by increasing the scratch resistance of the light emitting display panel DP, and also increase an adherence with a functional layer FL provided on the spacer 385 so as to prevent moisture and/or air from being injected from the outside. In some embodiments, the high adherence has a feature in that it may eliminate or reduce the problem of decreasing the adherence between layers if (e.g., when) the light emitting display panel DP has a flexible characteristic and is folded or unfolded. The cathode Cathode may be formed of a light-transmitting electrode or a

reflecting electrode. According to an embodiment, the cathode may be a transparent or semi-transparent electrode, and may be formed of a metal thin film having a small work function, including lithium (Li), calcium (Ca), lithium fluoride/calcium (LiF/Ca), lithium fluoride/aluminum (LiF/Al), aluminum (Al), silver (Ag), magnesium (Mg), and/or a compound thereof. In some embodiments, a transparent conductive oxide (TCO) such as indium tin oxide (ITO), indium zinc oxide (IZO), zinc oxide (ZnO) and/or indium oxide (In203) may be further provided on the metal thin film. The cathode may be integrally provided over the entire surface of the light emitting display panel DP.

The encapsulation layer 400 is on the cathode Cathode. The encapsulation layer 400 includes at least one inorganic layer and at least one organic layer, and in FIG. 15, it has a triple-layer structure including the first inorganic encapsulation layer 401, the organic encapsulation layer 402 and the second inorganic encapsulation layer 403. The encapsulation layer 400 may protect the light emitting layer EML formed of an organic material from moisture and/or oxygen that may inflow from the outside. According to an embodiment, the encapsulation layer 400 may include a structure in which an inorganic layer and an organic layer are sequentially further stacked.

Sensing insulating layers 501, 510 and 511 and a plurality of sensing electrodes 540 and 541 are on the encapsulation layer 400 for touch sensing. In an embodiment of FIG. 15, the touch is sensed in a capacitive type using two sensing electrodes 540 and 541, but according to an embodiment, the touch may be sensed in a self-cap type (or kind) using only one sensing electrode. A plurality of sensing electrodes 540 and 541 may be insulated (e.g., electrically insulated) with a second sensing insulating layer 510 interposed therebetween, a lower sensing electrode 541 is on the first sensing insulating layer 501, and an upper sensing electrode 540 is on the second sensing insulating layer 510, and the upper sensing electrode 540 is covered by the third sensing insulating layer 511. A plurality of sensing electrodes 540 and 541 may be electrically connected through an opening provided in the second sensing insulating layer 510. In some embodiments, the sensing electrodes 540 and 541 may include a metal and/or a metal alloy such as aluminum (Al), copper (Cu), silver (Ag), gold (Au), molybdenum (Mo), titanium (Ti), and/or tantalum (Ta) and may be composed of a single layer or a plurality of layers.

Color filters 230R, 230G, and 230B are on the third sensing insulating layer 511. The color filters 230R, 230G, and 230B include a red color filter 230R that transmits a red light, a green color filter 230G that transmits a green light and a blue color filter 230B that transmits a blue light. Each of the color filters 230R, 230G, and 230B may be provided to overlap the anode Anode of the light emitting diode (LED) in a plan view. Because light emitted from the light emitting layer EML may be emitted while being changed to a corresponding color while passing through the color filter, all of the light emitted from the light emitting layer EML may have the same color. However, in the light emitting layer EML, different colors of light may be displayed, and the displayed color may be enhanced by passing through the color filter of the same color.

According to an embodiment, the color filters 230R, 230G, and 230B may be replaced with a color conversion layer, or may further include a color conversion layer. The color conversion layer may include quantum dots.

In the embodiment of FIG. 15, a light blocking layer formed in black color to block visible light (or to reduce transmission of visible light) is not formed, and instead of the light blocking layer, the light blocking area of the color filter formed by overlapping at least two color filters is formed to replace the light blocking layer. In the embodiment of FIG. 15, the light blocking area of the color filter has the blue color filter 230B, the red color filter 230R, and the green color filter 230G sequentially stacked. The order in which the color filters are stacked may suitably vary according to an embodiment.

The light blocking area of the color filter, in which at least two color filters overlap, may be provided to overlap on a plane with the sensing electrodes 540 and 541, and not to overlap on a plane with the anode (Anode). This is to prevent the anode Anode and the light emitting layer EML capable of displaying the image from being obscured by the light blocking area of the color filter and the sensing electrodes 540 and 541.

Referring to FIG. 6, the light blocking area of the color filter where three color filters overlap is provided only in the area that overlaps the pixel defining layer 380 on a plane, and one side of the light blocking area of the color filter is provided inward from the corresponding side of the pixel defining layer 380.

Only one color filter may be provided in the area other than the light blocking area of the color filter, and light of the color of the color filter is transmitted to form the light transmitting area of the color filter. Below, the light transmitting area of the color filter, where only one color filter is provided, is also referred to as a second opening OPCF of the color filter because light is transmitted, and the second opening OPCF is an opening provided in the light blocking area of the color filter where at least two color filters overlap, and may correspond to an area where only one color filter is provided.

The area of the second opening OPCF is formed larger than the opening OP of the pixel defining layer 380, and the opening OP of the pixel defining layer 380 on a plane may be provided within the second opening OPCF of the color filter, and the gap between the opening OP of the pixel defining layer 380 and the second opening OPCF of the color filter is depicted as g1 in FIG. 11. As a result, the opening OP of the pixel defining layer 380 may be formed smaller than the second opening OPCF of the color filter, and a part of the pixel defining layer 380 may overlap the second opening OPCF of the color filter and be exposed at the front.

The color filters 230R, 230G, and 230B and the second openings OPCFr, OPCFg, and OPCFb according to the embodiment of FIG. 15 may include one of the features described above, such as the thickness, the width, the structure, the shape, etc.

A planarization layer 550 covering the color filters 230R, 230G, and 230B is on the color filters 230R, 230G, and 230B. The planarization layer 550 planarizes the upper surface of the light emitting display panel, and may be a transparent organic insulator (e.g., a transparent organic electrical insulator) containing at least one material selected from a group consisting of polyimide, polyamide, acryl resin, benzocyclobutene and phenol resin.

According to an embodiment, on top of the planarization layer 550, a low refractive layer and an additional planarization layer may be further provided to improve a front visibility and a light output efficiency of the display panel. Light may be emitted and refracted from the front by the low refractive layer, the additional planarization layer having a high refractive characteristic. In some embodiments, the low refractive layer and the additional planarization layer may be directly on the color filter while the planarization layer 550 is omitted according to an embodiment.

In some embodiments, a polarizer on the planarization layer 550 is not included. For example, the polarizer may serve to prevent or reduce deterioration of the display due to the user recognition as the external light is incident and reflected from the anode Anode or the side wall of the opening OP of the pixel defining layer 380, etc. However, the polarizers not only reduce the reflection of the external light, but also reduce the light emitted from the light emitting layer EML, so there is a drawback in that more electric power is consumed to display a set or certain luminance. To reduce the power consumption, the light emitting display device of the present embodiment may not include the polarizer.

The present embodiment already includes a structure that covers the side of the anode Anode with the pixel defining layer 380 to reduce the degree of reflection from the anode Anode, and the light blocking area of the color filter in which at least two color filters overlap is formed to reduce the degree of incident light on the anode to prevent or reduce the deterioration of the display quality due to reflection. Therefore, there is no need to form a polarizer separately on the front side of the light emitting display panel DP.

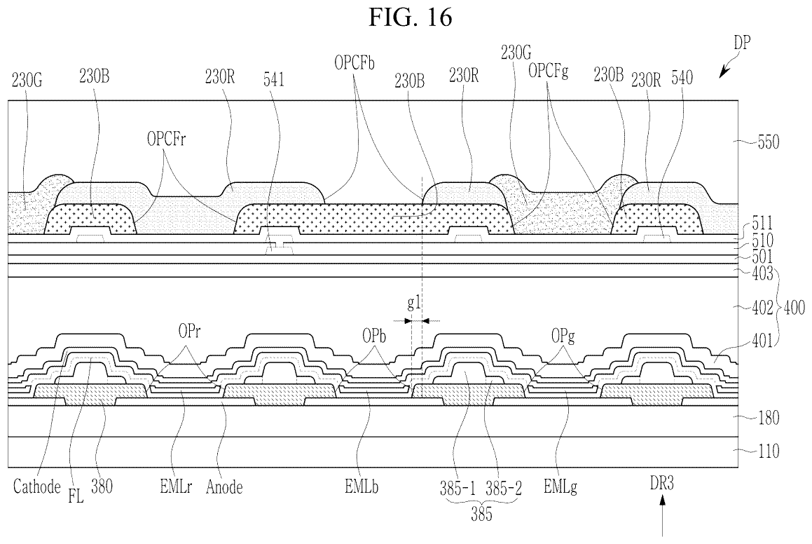

In the above, as shown in FIG. 15, the embodiment in which the light blocking area of the color filter, where at least two color filters overlap, is formed by overlapping three color filters has been described. However, according to an embodiment, two color filters may overlap to form the light blocking area of the color filter, and this is described with respect to FIG. 16.

FIG. 16 is a schematic cross-sectional view of a display panel according to another embodiment.

FIG. 16 is a drawing corresponding to FIG. 15, only the color filters 230R, 230G, and 230B differ from FIG. 15, and the lower structure of the third sensing insulating layer 511 is the same as that of FIG. 15. Below, the upper structure of the third sensing insulating layer 511, which is different from FIG. 15, is described.

Referring to FIG. 16, a light blocking layer that blocks or reduces transmission of visible light is not formed, and a blue color filter 230B and a red color filter 230R are sequentially overlapped to block or reduce transmission of visible light. The order in which the color filters are stacked may suitably vary depending on the embodiment.

In some embodiments, the light blocking area of the color filter where two color filters overlap is where the blue color filter 230B and the red color filter 230R overlap, and some areas of the light blocking area of the color filter also have a part overlapping the green color filter 230G. However, the green color filter 230G is not formed entirely on the light blocking area of the color filter, and unlike the embodiment of FIG. 15, this is an embodiment in which the light blocking area of the color filter is formed of only two color filters. The light blocking area of the color filter, where two color filters overlap, is provided only in the area that overlaps the pixel defining layer 380 on the plane, and one side of the light blocking area of the color filter is provided inward from the corresponding side of the pixel defining layer 380.

Only one color filter may be provided in an area other than the light blocking area of the color filter, and light of the color of the color filter is transmitted, thereby forming the light transmitting area of the color filter or the second opening OPCF of the color filter. The area of the second opening OPCF may be formed larger than the opening OP of the pixel defining layer 380, and on a plane, the opening OP of the pixel defining layer 380 may be provided within the second opening OPCF of the color filter.

In addition to the pixel defining layer 380, the light blocking area of the color filter may overlap on a plane the spacer 385 and the plurality of sensing electrodes 540 and 541.

In some embodiments, the plurality of sensing electrodes 540 and 541 are flatly covered by the light blocking area of the color filter. As a result, when viewed from the front of the display panel DP, the spacer 385 and the plurality of sensing electrodes 540 and 541 may not be visible due to the light blocking area of the color filter.

According to an embodiment, the color filters 230R, 230G, and 230B may be replaced with color conversion layers, or color conversion layers may be further included. The color conversion layers may include quantum dots.

The color filters 230R, 230G, and 230B and the second openings OPCFr, OPCFg, and OPCFb according to the embodiment of FIG. 16 may include one of the features described above, such as the thickness, the width, the structure, the shape, etc.

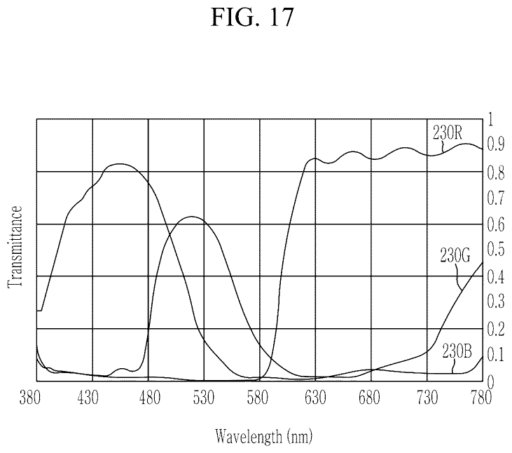

Below, FIG. 17 shows how two color filters may replace the role of the light blocking layer.

FIG. 17 is a graph showing a transmittance according to a wavelength of a color filter.

FIG. 17 is the transmittance graph for the wavelength of each color filter 230R, 230G, and 230B, so light in the wavelength range indicated at a high level is transmitted. Referring to FIG. 17, it may be confirmed that the other parts except the wavelength bands transmitted by each color filter 230R, 230G, and 230B have a transmittance of less than 10%, and that when three or two color filters overlap, there is almost no transmitted wavelength band. Therefore, it may be confirmed that overlapping at least two color filters may replace the role of the light blocking layer, so that overlapping three color filters, such as in FIG. 7, or overlapping two color filters, such as in FIG. 16, may replace the light blocking layer.

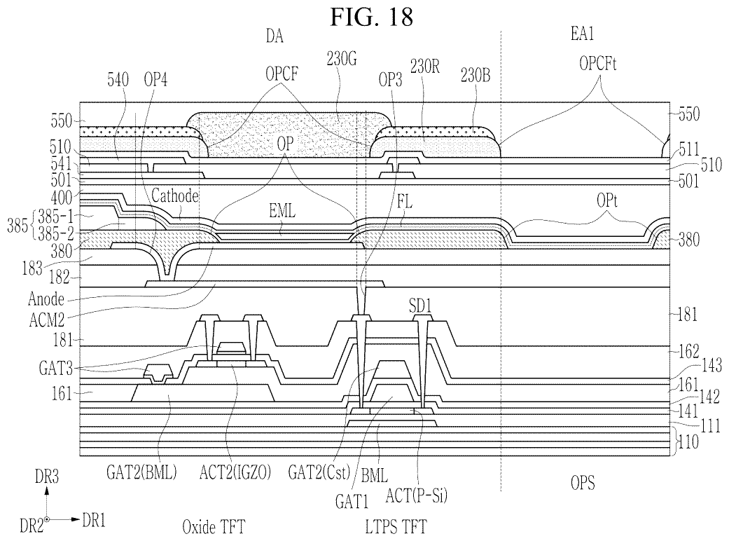

Below, FIG. 18. shows a more detailed cross-sectional structure of an embodiment that does not include a light blocking layer while forming the color filters 230R, 230G, and 230B by overlapping them. FIG. 18 illustrates an embodiment in which the blue color filter 230B and the red color filter 230R are overlapped to form the light blocking area of the color filter.

FIG. 18 is a cross-sectional view of a light emitting display device according to an embodiment.

FIG. 18 shows the stacking structure of the first component area EA1 in addition to the stacking structure of the display area DA.

The light emitting display device may be broadly divided into a lower panel layer and an upper panel layer, and the lower panel layer may be where the light emitting diodes and the pixel circuit units that make up the pixels are provided, and may include the encapsulation layer 400 covering it. In some embodiments, the pixel circuit unit may include the second organic layer 182 and the third organic layer 183 and mean a configuration thereunder, and the light emitting diode may mean a configuration provided above the third organic layer 183 and below the encapsulation layer 400. A structure provided above the encapsulation layer 400 may correspond to the upper panel layer.

Referring to FIG. 18, a metal layer BML is on a substrate 110.

The substrate 110 may include a material that does not bend due to a rigid characteristic such as glass, or a flexible material that can be bent such as plastic and/or polyimide. In embodiments of the flexible substrate, as shown in FIG. 18, it may have a structure in which a double-layered structure of polyimide and a barrier layer formed of an inorganic insulating material (e.g., an inorganic electrically insulating material) thereon is formed.

The metal layer BML may be provided at a position overlapping the channel of the driving transistor T1 on a plane among the subsequent first semiconductor layer and is also referred to as a lower shielding layer. The metal layer BML may include a metal such as copper (Cu), molybdenum (Mo), aluminum (Al), titanium (Ti), and/or a metal alloy.

A buffer layer 111 covering the substrate 110 and the metal layer BML is on the substrate 110 and the metal layer BML. The buffer layer 111 serves to block or reduce the penetration of impure elements into a first semiconductor layer ACT(P-Si), and may be an inorganic insulating layer including silicon oxide (SiOx), silicon nitride (SiNx), silicon oxynitride (SiONx), etc.

The first semiconductor layer ACT(P-Si) formed of a silicon semiconductor (e.g., a polycrystalline semiconductor (P-Si)) is on the buffer layer 111. The first semiconductor layer 130 includes a channel of a polycrystalline transistor LTPS TFT including the driving transistor T1 and a first region and a second region on both sides (e.g., two opposing sides) thereof. In some embodiments, the polycrystalline transistor LTPS TFT may include not only the driving transistor T1 but also various suitable switching transistors and/or compensation transistors. In some embodiments, both sides (e.g., two opposing sides) of the channel of the first semiconductor layer ACT(P-Si) have a region having a conductive layer (e.g., an electrically conductive layer) characterized by plasma treatment and/or doping, so that it may serve as a first electrode and a second electrode of the transistor.

A first gate insulating layer 141 may be on the first semiconductor layer ACT (P-Si). The first gate insulating layer 141 may be an inorganic insulating layer including silicon oxide (SiOx), silicon nitride (SiNx), silicon oxynitride (SiONx), and/or the like.

A first gate conductive layer GAT1 including a gate electrode of the polycrystalline transistor LTPS TFT may be on the first gate insulating layer 141. In the first gate conductive layer GAT1, a first scan line or a light emitting control line may be provided in addition to the gate electrode of the polycrystalline transistor LTPS TFT. The first gate conductive layer may include a metal such as copper (Cu), molybdenum (Mo), aluminum (Al), or titanium (Ti) and/or a metal alloy, and may be configured as a single layer or a plurality of layers.

After forming the first gate conductive layer, plasma treatment and/or a doping process may be performed to make the exposed region of the first semiconductor layer conductive (e.g., electrically conductive). For example, the first semiconductor layer ACT (P—Si) covered by the first gate conductive layer GAT1 is not conductive (e.g., is not electrically conductive), and the part of the first semiconductor layer ACT (P—Si) not covered by the first gate conductive layer GAT1 may have the same characteristic as the conductive layer.

A second gate insulating layer 142 may be on the first gate conductive layer and the first gate insulating layer 141. The second gate insulating layer 142 may be an inorganic insulating layer including silicon oxide (SiOx), silicon nitride (SiNx), silicon oxynitride (SiONx), and/or the like.

A second gate conductive layer GAT2 including one electrode GAT2 Cst of a storage capacitor Cst and a lower shielding layer GAT2 (BML) of an oxide transistor Oxide TFT may be on the second gate insulating layer 142. The lower shielding layer GAT2 (BML) of the oxide transistor Oxide TFT is below the channel of the oxide transistor Oxide TFT, respectively, thereby serving to shield the channel from optical and/or electromagnetic interference provided to the channel from the lower side. In some embodiments, one electrode GAT2 Cst of the storage capacitor Cst overlaps the gate electrode of the driving transistor T1 to form a storage capacitor Cst. According to an embodiment, the second gate conductive layer GAT2 may further include a scan line, a control line, and/or a voltage line. The second gate conductive layer GAT2 may include a metal and/or a metal alloy such as copper (Cu), molybdenum (Mo), aluminum (Al), and/or titanium (Ti), and may be configured as a single layer or a plurality of layers.

A first interlayer insulating layer 161 may be on the second gate conductive layer GAT2. The first interlayer insulating layer 161 may include an inorganic insulating layer including silicon oxide (SiOx), silicon nitride (SiNx), silicon oxynitride (SiOxNy), and/or the like, and an inorganic insulating material (e.g., an inorganic electrically insulating material) may be thickly formed according to an embodiment.

An oxide semiconductor layer ACT2 (IGZO) including the channel, the first region and the second region of the oxide transistor oxide TFT may be on the first interlayer insulating layer 161.

A third gate insulating layer 143 may be on the oxide semiconductor layer ACT2 (IGZO). The third gate insulating layer 143 may be on the entire surface on the oxide semiconductor layer ACT2 (IGZO) and the first interlayer insulating layer 161. The third gate insulating layer 143 may include an inorganic insulating layer (e.g., an inorganic electrically insulating layer) including silicon oxide (SiOx), silicon nitride (SiNx), silicon oxynitride (SiONx), and/or the like.

On the third gate insulating layer 143, a third gate conductive layer GAT3 including the gate electrode of the oxide transistor oxide TFT may be provided. The gate electrode of the oxide transistor oxide TFT may overlap the channel. The third gate conductive layer GAT3 may further include a scan line and/or a control line, and may include a connecting electrode connected to the lower shielding layer GAT2 (BML) of the oxide transistor Oxide TFT. The third gate conductive layer GAT3 may include a metal and/or a metal alloy such as copper (Cu), molybdenum (Mo), aluminum (Al), and/or titanium (Ti), and may be configured as a single layer or a plurality of layers.

A second interlayer insulating layer 162 may be on the third gate conductive layer GAT3. The second interlayer insulating layer 162 may have a single-layered or multi-layered structure. The second interlayer insulating layer 162 may include an inorganic insulating material (e.g., an inorganic electrically insulating material) such as silicon nitride (SiNx), silicon oxide (SiOx), and/or silicon oxide (SiOxNy), and may include an organic material according to an embodiment.

On the second interlayer insulating layer 162, a first data conductive layer SD1 including a connecting electrode that may be connected to the first region and the second region of each of the polycrystalline transistor LTPS TFT and the oxide transistor Oxide TFT may be provided. The first data conductive layer SD1 may include a metal such as aluminum (Al), copper (Cu), molybdenum (Mo), titanium (Ti), and/or a metal alloy, and may be configured as a single layer or a plurality of layers.

A first organic layer 181 may be on the first data conductive layer SD1. The first organic layer 181 may be an organic insulator (e.g., an organic electrical insulator) including an organic material, and the organic material may include at least one material selected from a group consisting of polyimide, polyamide, acryl resin, benzocyclobutene, and phenol resin.

A second data conductive layer including an anode connecting electrode ACM2 may be on the first organic layer 181. The second data conductive layer may include a data line and/or a driving voltage line. The second data conductive layer SD2 may include a metal and/or a metal alloy such as aluminum (Al), copper (Cu), molybdenum (Mo), and/or titanium (Ti), and may be configured as a single layer or a plurality of layers.

A second organic layer 182 and a third organic layer 183 are on the second data conductive layer, and an anode connection opening OP4 is formed in the second organic layer 182 and the third organic layer 183. The anode connecting electrode ACM2 is electrically connected to the anode Anode through the anode connection opening OP4. The second organic layer 182 and the third organic layer 183 may be organic insulators (e.g., organic electrical insulators), and may include at least one material selected from the group consisting of polyimide, polyamide, acryl resin, benzocyclobutene, and phenol resin. According to an embodiment, the third organic layer 183 may be omitted.

On the anode Anode, the pixel defining layer 380 covering at least a part of the anode Anode while having an opening OP exposing the anode Anode may be provided. The pixel defining layer 380 may be a black pixel defining layer formed of an organic material having a black color so that light applied from the outside is not reflected back to the outside, and according to an embodiment, it may be formed of a transparent organic material. Therefore, according to an embodiment, the pixel defining layer 380 may include an organic material of a negative-type black color, and may include a black color pigment.

A spacer 385 is on the pixel defining layer 380. The spacer 385 includes a first part 385-1 having a high height and provided in a narrow area and a second part 385-2 having a low height and provided in a wide area. The spacer 385, unlike the pixel defining layer 380, may be formed of a transparent organic insulating material (e.g., a transparent organic electrically insulating material). According to an embodiment, the spacer 385 may be formed of a positive-type transparent organic material.

On the anode Anode, the spacer 385, and the pixel defining layer 380, the functional layer FL, and the cathode Cathode are sequentially formed, and in the display area DA and the first component area EA1, the functional layer FL and the cathode Cathode may be provided in the entire region. The light emitting layer EML is between the functional layers FL, and the light emitting layer EML may be provided only within the opening OP of the pixel defining layer 380. Hereinafter, the functional layer FL and the light emitting layer EML may be combined and referred to as an intermediate layer. The functional layer FL may include at least one selected from among an auxiliary layer such as an electron injection layer, an electron transport layer, a hole transport layer, and a hole injection layer, the hole injection layer and the hole transport layer may be provided under the light emitting layer EML, and the electron transport layer and the electron injection layer may be provided on the light emitting layer EML.

An encapsulation layer 400 is on the cathode Cathode. The encapsulation layer 400 may include at least one inorganic layer and at least one organic layer, and according to an embodiment, may have a triple-layer structure including a first inorganic encapsulation layer, an organic encapsulation layer, and a second inorganic encapsulation layer. The encapsulation layer 400 may protect the light emitting layer EML from moisture and/or oxygen that may inflow from the outside. According to an embodiment, the encapsulation layer 400 may include a structure in which an inorganic layer and an organic layer are sequentially further stacked.

Sensing insulating layers 501, 510, and 511 and a plurality of sensing electrodes 540 and 541 are on the encapsulation layer 400 for touch sensing. In the embodiment of FIG. 18, the touch may be sensed in a capacitive type (or kind) using two sensing electrodes 540 and 541.

In some embodiments, a first sensing insulating layer 501 is formed on the encapsulation layer 400, and a plurality of sensing electrodes 540 and 541 are formed on top of the first sensing insulating layer 501. A plurality of sensing electrodes 540 and 541 may be insulated (e.g., electrically insulated) via the second sensing insulating layer 510 therebetween, and the parts may be electrically connected through the opening provided on the sensing insulating layer 510. In some embodiments, the sensing electrodes 540 and 541 include a metal and/or metal alloy such as aluminum (Al), copper (Cu), silver (Ag), gold (Au), molybdenum (Mo), titanium (Ti), tantalum (Ta), etc., and may be composed of a single layer or a plurality of layers. The third sensing insulating layer 511 is formed on the sensing electrode 540.

Color filters 230R, 230G, and 230B are on the third sensing insulating layer 511.

In the embodiment of FIG. 18, the light blocking layer is not included, and the role of the light blocking layer may be performed by the overlapped color filters 230R and 230B, and the overlapped color filters 230R and 230B may overlap on a plane with the sensing electrodes 540 and 541. The overlapped color filters 230R and 230B have a second opening OPCF, and the second opening OPCF of the overlapped color filters 230R and 230B overlaps the opening OP of the pixel defining layer 380 on a plane. In some embodiments, the second opening OPCF of the overlapped color filters 230R and 230B may be formed wider than the opening OP of the pixel defining layer 380. As a result, the anode (Anode) that overlaps the opening OP of the pixel defining layer 380 (e.g., exposed by the opening OP of the pixel defining layer 380) may have a structure that is not obscured on a plane by the overlapped color filters 230R and 230B. This is to prevent the anode and the light emitting layer EML, which may display the image, from being obscured by the overlapped color filters 230R and 230B and the sensing electrodes 540 and 541. In some embodiments, the overlapped color filters 230R and 230B have a structure that overlaps on a plane the anode connection opening OP4.

One color filter may be provided inside the second opening OPCF of the overlapped color filters 230R and 230B, and in FIG. 18, the green color filter 230G is provided. According to an embodiment, the color filters 230R, 230G, and 230B may be replaced with color conversion layers or may further include color conversion layers. The color conversion layer may include quantum dots.

The color filters 230R, 230G, and 230B and the second opening OPCF according to the embodiment of FIG. 18 may include one of the features described above, such as the thickness, the width, the structure, the shape, etc.

On the color filters 230R, 230G, and 230B, a planarization layer 550 is provided, covering the color filters 230R, 230G, and 230B. The planarization layer 550 planarizes the upper surface of the light emitting display device, and may be a transparent organic insulator (e.g., a transparent organic electrical insulator) containing at least one material selected from a group consisting of polyimide, polyamide, acryl resin, benzocyclobutene and phenol resin.

According to the embodiment, on top of the planarization layer 550, a low-refractive layer and an additional planarization layer may be further provided to improve front visibility and light output efficiency of the display device. Light may be emitted while being refracted to the front by the low-refractive layer, the additional planarization layer having a high-refractive characteristic. In some embodiments, the low-refractive layer and the additional planarization layer may be directly on the color filter while the planarization layer 550 is omitted according to an embodiment.

In the present embodiment, a polarizer on the planarization layer 550 is not included. For example, the polarizer may serve to prevent or reduce a display deterioration due to the user recognition as the external light is incident and reflected from the anode Anode and/or the like. However, in the present embodiment, the pixel defining layer 380 covers the sides of the anode to reduce the amount of reflection from the anode Anode, and the overlapped color filters 230R and 230B are also formed to reduce the amount of incident light to prevent or reduce deterioration of the display quality due to the reflection. Therefore, there is no need to form a polarizer separately on the front of the display panel DP.

FIG. 18 also illustrates the cross-sectional structure of the first component area EA1, which is formed to allow light to be transmitted into a part of the display area DA in addition to the stacking structure of the display area DA.

In FIG. 18, the first component area EA1 corresponds to the photosensor area OPS, and each photosensor area OPS has a photosensor area opening OPt and OPCFt so as to not overlap the pixel defining layer 380 and the light blocking area of the color filter where at least two color filters overlap on a plane.

The photosensor area OPS of the first component area EA1 may not include layers that block light (or reduce transmission of visible light), such as a metal layer and/or a semiconductor layer. For reference, the first optical element (ES1; referring to FIG. 2) is on the back surface of the first component area EA1, and the front surface of the light emitting display device may be detected through the photosensor area OPS provided in the first component area EA1.

The layered structure of the first component area EA1 of some embodiments is described as follows.

On the substrate 110, a buffer layer 111 that is an inorganic insulating layer (e.g., an inorganic electrically insulating layer) is provided, and thereon, a first gate insulating layer 141 and a second gate insulating layer 142 that are inorganic insulating layers (e.g., inorganic electrically insulating layers) are sequentially provided. In some embodiments, on the second gate insulating layer 142, a first interlayer insulating layer 161, a third gate insulating layer 143, and a second interlayer insulating layer 162 that are inorganic insulating layers (e.g., inorganic electrically insulating layers) are sequentially stacked.

On the second interlayer insulating layer 162, a first organic layer 181, a second organic layer 182, and a third organic layer 183, which are organic insulators (e.g., organic electrical insulators), are sequentially stacked.

A functional layer FL may be on the third organic layer 183, and a cathode (Cathode) may be provided thereon.

An encapsulation layer 400 is on the cathode (Cathode), and the sensing insulating layers 501, 510, and 511 are sequentially provided thereon. The encapsulation layer 400 may have a triple-layer structure including a first inorganic encapsulation layer, an organic encapsulation layer, and a second inorganic encapsulation layer. In some embodiments, the sensing insulating layers 501, 510, and 511 may all be inorganic insulating layers (e.g., inorganic electrically insulating layers).

A planarization layer 550 may be on the sensing insulating layers 501, 510, and 511.

As above described, in the first component area EA1, a metal layer, a first semiconductor layer, a first gate conductive layer, a second gate conductive layer, an oxide semiconductor layer, a third gate conductive layer, a first data conductive layer, a second data conductive layer, and an anode are not provided. In some embodiments, the light emitting layer EML and the sensing electrodes 540 and 541 are not provided.

In some embodiments, in the photosensor area OPS of the first component area EA1, the photosensor area openings OPt and OPCFt are formed in the pixel defining layer 380 and the light blocking area of the color filter, respectively, so that the pixel defining layer 380 and the color filter may not be provided. As a result, light may pass through the photosensor area OPS.

According to some embodiments, the photosensor area openings OPt and OPCFt may not be formed in the pixel defining layer 380 and the light blocking area of the color filter, respectively. In some embodiments, the sensor on the back may be used if (e.g., when) light of a wavelength other than visible rays (e.g., visible light) may be transmitted even if (e.g., when) there is the pixel defining layer 380 and the light blocking area of the color filter.

In the above, the embodiment in which a total of three organic layers are formed, and the opening for an anode connection is formed in the second organic layer and the third organic layer, has been described. However, the organic layer may be formed of at least two layers, and in some embodiments, the opening for the anode connection may be provided in the upper organic layer provided away from the substrate, and a lower organic layer opening may be provided in the lower organic layer.

While the subject matter of this disclosure has been described in connection with what is presently considered to be practical example embodiments, it is to be understood that the disclosure is not limited to the disclosed embodiments, but, on the contrary, is intended to cover various suitable modifications and equivalent arrangements included within the spirit and scope of the appended claims, and equivalents thereof.

### DESCRIPTION OF SYMBOLS

Description of symbols

| | |
|---|---|
| 230R, 230G, 230B: color filter | 380: pixel defining layer |
| OP, OPr, OPg, OPb: opening of | |
| pixel defining layer | |
| OPCF, OPCFr, | |
| OPCFg, OPCFb: second | |
| opening of color filter | |
| Anode: anode | Cathode: cathode |
| EML: light emitting layer | FL: function layer |
| 1000: display device | DP: display panel |
| 110: substrate | 180, 181, 182, 183: organic layer |
| 141, 142, 143: gate | |
| insulating layer | |
| 161, 162: interlayer | |
| insulating layer | |
| 385, 385-1, 385-2: spacer | |
| 400, 401, 402, 403: encapsulation | |
| layer | |
| 501, 510, 511: sensing | |
| insulating layer | |
| 540, 541: sensing electrode | |
| 550: planarization | DA, DA1-1, DA1-2: |
| layer | display area |
| EA, EA1, EA2: | OPt, OPCFt: photosensor |
| component area | area opening |

What is claimed is:

1. A light emitting display device comprising:
a substrate;
a plurality of anodes on the substrate;
a pixel defining layer having a plurality of first openings that overlap each of the plurality of anodes;
a plurality of light emitting layers each provided within the plurality of first openings of the pixel defining layer;
a cathode on the plurality of light emitting layers and the pixel defining layer;
an encapsulation layer over the cathode; and
a plurality of color filters on the encapsulation layer and corresponding to different colors,
wherein the plurality of color filters comprise a light blocking area of the color filter in which at least two color filters among the plurality of color filters overlap, and a plurality of second openings in which only one color filter among the plurality of color filters is provided, and
the light blocking area of the color filter has a side of a stepped shape in which an end of the second color filter above is provided inward compared to the end of the first color filter below among the plurality of color filters.

2. The light emitting display device of claim 1, wherein:
among the plurality of color filters, the second color filter provided above is formed thicker than the first color filter provided below.

3. The light emitting display device of claim 2, wherein:
the light blocking area of the color filter is where the blue color filter, red color filter, and green color filter overlap, and
each of the plurality of second openings overlap one color filter among the blue color filter, the red color filter, and the green color filter.

4. The light emitting display device of claim 2, wherein:
the light blocking area of the color filter is where the blue color filter and the red color filter overlap, and
each of the plurality of second openings overlap one color filter among a blue color filter, a red color filter, and a green color filter.

5. The light emitting display device of claim 2, further comprising:
a plurality of photosensor areas formed corresponding to optical elements, and
a photosensor area first opening is provided around the photosensor area in the pixel defining layer, and a photosensor area second opening is provided in the light blocking area of the color filter.

6. The light emitting display device of claim 5, wherein:
the photosensor area second opening is where a blue color filter, a red color filter, and a green color filter are not provided.

7. The light emitting display device of claim 6, wherein:
the photosensor area second opening is positioned an adjacent red second opening and blue second opening, and
the light blocking area of the color filter is not between the photosensor area second opening and the red second opening or the blue second opening.

8. The light emitting display device of claim 2, wherein:
each planar shape of the plurality of first openings and the plurality of second openings has the shape of a circle, an ellipse, or a polygon.

9. The light emitting display device of claim 8, wherein:
at least one selected from among the plurality of first openings and the plurality of second openings has an oval shape.

10. The light emitting display device of claim 8, wherein:
the first opening and the second opening, which overlap each other on a plane, are formed at regular intervals on a plane.

11. A light emitting display device comprising:
a substrate;
a plurality of anodes on the substrate;
a pixel defining layer having a plurality of first openings that each overlap the plurality of anodes;
a plurality of light emitting layers each provided within the plurality of first openings of the pixel defining layer;
a cathode on the plurality of light emitting layers and the pixel defining layer; and
an encapsulation layer over the cathode; and
a plurality of color filters are on the encapsulation layer and correspond to different colors,
wherein the plurality of color filters comprises a light blocking area of the color filter in which at least two color filters among the plurality of color filters overlap, and a plurality of second openings in which only one color filter among the plurality of color filters is provided, and
the light blocking area of the color filter has a shape in which the end or step part of the first color filter below among the plurality of color filters is covered by the second color filter above.

12. The light emitting display device of claim 11, wherein:
among the plurality of color filters, the second color filter above is formed thicker than the first color filter below.

13. The light emitting display device of claim 12, wherein:
the light blocking area of the color filter is where the blue color filter, red color filter, and green color filter overlap, and
each of the plurality of second openings overlap one color filter among the blue color filter, the red color filter, and the green color filter.

14. The light emitting display device of claim 12, wherein:
the light blocking area of the color filter is where the blue color filter and the red color filter overlap, and
each of the plurality of second openings overlap one color filter among a blue color filter, a red color filter, and a green color filter.

15. The light emitting display device of claim 12, further comprising:
a plurality of photosensor areas corresponding to optical elements, and
a photosensor area first opening is provided around the photosensor area in the pixel defining layer, and a photosensor area second opening is provided in the light blocking area of the color filter.

16. The light emitting display device of claim 15, wherein:
the photosensor area second opening is where a blue color filter, a red color filter, and a green color filter are not provided.

17. The light emitting display device of claim 16, wherein:
the photosensor area second opening is between an adjacent red second opening and blue second opening, and
the light blocking area of the color filter is not between the photosensor area second opening and the red second opening or the blue second opening.

18. The light emitting display device of claim 12, wherein:
the planar shape of each of the plurality of first openings and the plurality of second openings is a circle, an ellipse, or a polygon.

19. The light emitting display device of claim 18, wherein:
at least one selected from among the plurality of first openings and the plurality of second openings has an oval shape.

20. The light emitting display device of claim 18, wherein:
the first opening and the second opening, which overlap each other on a plane, are formed at regular intervals on a plane.

21. An electronic apparatus, comprising:
a processor to provide input image data; and
a light emitting display device to display an image based on the input image data,
wherein the light emitting display device comprises:
a substrate;
a plurality of anodes on the substrate;
a pixel defining layer having a plurality of first openings that overlap each of the plurality of anodes;
a plurality of light emitting layers each provided within the plurality of first openings of the pixel defining layer;
a cathode on the plurality of light emitting layers and the pixel defining layer;
an encapsulation layer over the cathode; and
a plurality of color filters on the encapsulation layer and corresponding to different colors,
wherein the plurality of color filters comprise a light blocking area of the color filter in which at least two color filters among the plurality of color filters overlap, and a plurality of second openings in which only one color filter among the plurality of color filters is provided, and
the light blocking area of the color filter has a side of a stepped shape in which an end of the second color filter provided above is provided inward compared to the end of the first color filter provided below among the plurality of color filters.
